(19) United States
(12) Patent Application Publication
(10) Pub. No.: US 2026/0120754 A1
(43) Pub. Date: Apr. 30, 2026

(54) SEMICONDUCTOR MEMORY DEVICE AND MEMORY SYSTEM INCLUDING THE SAME

(71) Applicant: Samsung Electronics Co., Ltd., Suwon-si (KR)

(72) Inventors: Yujin Kim, Suwon-si (KR); Jinwoo Han, Suwon-si (KR)

(21) Appl. No.: 19/321,532

(22) Filed: Sep. 8, 2025

(30) Foreign Application Priority Data
Oct. 28, 2024 (KR) 10-2024-0148310

(51) Int. Cl. G11C 11/4097; G11C 11/4091; G11C 11/4094

(52) U.S. Cl. CPC G11C 11/4097; G11C 11/4091; G11C 11/4094

(57) ABSTRACT

A semiconductor memory device includes memory cells, local bitlines, wordlines, global bitlines, local bitline multiplexers and sense amplifiers. The memory cells are arranged along first, second and third directions. The local bitlines and the wordlines are connected to the memory cells. Each of the local bitlines extends in the first direction. Each of the wordlines extends in the third direction. The global bitlines are disposed on the local bitlines. The local bitline multiplexers control electrical connections between the local bitlines and the global bitlines. The sense amplifiers drive the local bitlines and the global bitlines. Memory cells, which are disposed at a same level, adjacent in the second direction, and connected to different local bitlines, are electrically connected to a same wordline.

### CROSS-REFERENCE TO RELATED APPLICATION

This application claims priority under 35 USC § 119 to Korean Patent Application No. 10 -2024-0148310 filed on Oct. 28, 2024 in the Korean Intellectual Property Office (KIPO), the content of which is herein incorporated by reference in its entirety.

### BACKGROUND

### 1. Technical Field

Example embodiments relate generally to semiconductor integrated circuits, and more particularly to three-dimensional (3D) semiconductor memory devices and memory systems including the 3D semiconductor memory devices.

### 2. Description of the Related Art

The demand for the miniaturization, multi-function and/or high-performance in electronic products drives the need for high-capacity semiconductor memory devices. To provide the high-capacity semiconductor memory devices, high integration density is demanded. Since integration densities of existing two-dimensional (2D) semiconductor memory devices may primarily be determined by the area occupied by a unit memory cell, the integration densities of 2D semiconductor memory devices have been increasing by shrinking the size of the unit memory cell, but remain limited. Therefore, three-dimensional (3D) semiconductor memory devices have been proposed to increase a memory capacity by stacking a plurality of memory cells on a substrate in a vertical direction.

### SUMMARY

At least one example embodiment of the present disclosure provides a semiconductor memory device capable of having improved electrical characteristics and reliability.

At least one example embodiment of the present disclosure provides a memory system including the semiconductor memory device.

According to example embodiments, a semiconductor memory device includes a plurality of cell string rows arranged on a first substrate, each cell string row being spaced apart from an adjacent cell string row in a second direction and including a plurality of cell strings arranged along a third direction, and each cell string including memory cells stacked vertically along a first direction, wherein the first direction is perpendicular to an upper surface of the first substrate, the second and third directions are parallel to the upper surface of the first substrate and intersect each other, a plurality of local bitlines on the first substrate, each of the plurality of local bitlines being electrically connected to memory cells of corresponding cell string, each of the plurality of local bitlines extending in the first direction, a plurality of wordlines on the first substrate, each of the plurality of wordlines being electrically connected to the memory cells disposed at the same level of the corresponding cell string row, each of the plurality of wordlines extending in the third direction, a plurality of global bitlines selectively and electrically connected to the plurality of local bitlines, a plurality of local bitline multiplexers configured to control electrical connections between the plurality of local bitlines and the plurality of global bitlines, and a plurality of sense amplifiers electrically connected to the plurality of global bitlines, and configured to perform sensing operations on memory cells connected to the local and global bitlines, wherein memory cells disposed at the same level of two adjacent cell string rows, which are connected to different local bitlines, are electrically connected to a merged wordline.

According to example embodiments, a semiconductor memory device includes a first local bitline and a second local bitline on a first substrate, each of the first and second local bitlines extending in a first direction perpendicular to an upper surface of the first substrate, the first and second local bitlines being spaced apart from each other in a second direction parallel to the upper surface of the first substrate, first memory cells on the first substrate, the first memory cells stacked vertically along the first direction between the first and second local bitlines and being electrically connected to the first local bitline, second memory cells on the first substrate, the second memory cells stacked vertically along the first direction between the first and second local bitlines and being electrically connected to the second local bitline, wordlines on the first substrate, each of the wordlines extending in a third direction parallel to the upper surface of the first substrate and intersecting the second direction, each of the wordlines being electrically connected to memory cells disposed at the same level among the first and second memory cells, a first global bitline and a second global bitline selectively and electrically connected to the first local bitline and the second local bitline, a first local bitline multiplexer and a second local bitline multiplexer configured to control electrical connections between the first and second local bitlines and the first and second global bitlines, and a first sense amplifier and a second sense amplifier electrically connected to the first global bitline and the second global bitline respectively, the first and second sense amplifiers configured to perform sensing operations on memory cells electrically connected to the first and second local bitlines and the first and second global bitlines.

According to example embodiments, a memory system includes a memory controller and a semiconductor memory device controlled by the memory controller, the semiconductor memory device includes a plurality of memory cells on a first substrate, the plurality of memory cells being arranged along a first direction, a second direction and a third direction, the first direction being perpendicular to an upper surface of the first substrate, the second and third directions being parallel to the upper surface of the first substrate and intersecting each other, a plurality of local bitlines on the first substrate, the plurality of local bitlines being electrically connected to the plurality of memory cells, each of the plurality of local bitlines extending in the first direction, a plurality of wordlines on the first substrate, the plurality of wordlines being electrically connected to the plurality of memory cells, each of the plurality of wordlines extending in the third direction, a plurality of global bitlines selectively and electrically connected to the plurality of local bitlines, a plurality of local bitline multiplexers configured to control electrical connections between the plurality of local bitlines and the plurality of global bitlines, and a plurality of sense amplifiers electrically connected to the plurality of global bitlines, the plurality of sense amplifiers configured to perform sensing operations on memory cells connected to the plurality of local bitlines and the plurality of global bitlines, and wherein memory cells, which are disposed at the same level, adjacent in the second direction, and connected to different local bitlines, are electrically connected to a merged wordline.

The semiconductor memory device and the memory system according to example embodiments may be implemented with the wordline merging structure in which two adjacent wordlines connected to two memory cells, which are disposed at the same level and do not share a local bitline, are merged into one wordline. In addition, the local bitline multiplexer that controls the electrical connection between the local bitline and the global bitline may be disposed on each local bitline, and the local bitline may be driven by the sense amplifier connected to the global bitline. Accordingly, the number of sense amplifiers may be reduced and the size of each sense amplifier may increase because the sense amplifier does not need to be connected to each local bitline, and thus the semiconductor memory device may have improved electrical characteristics and improved reliability. Moreover, since the number of sense amplifiers is reduced and the size of each sense amplifier increases, bonding defects caused by misalignment may be reduced when the cell wafer and the peripheral wafer are connected to each other by the bonding scheme in the POC structure (or COP structure).

### BRIEF DESCRIPTION OF THE DRAWINGS

Illustrative, non-limiting example embodiments will be more clearly understood from the following detailed description taken in conjunction with the accompanying drawings.

FIG. 1 is a perspective view of a semiconductor memory device according to example embodiments.

FIG. 2 is a circuit diagram illustrating an example of a semiconductor memory device of FIG. 1.

FIGS. 3 and 4 are perspective views of examples of a semiconductor memory device of FIG. 1.

FIG. 5 is a perspective view of a semiconductor memory device according to example embodiments.

FIG. 6 is a cross-sectional view of a semiconductor memory device of FIG. 5.

FIGS. 7 and 8 are circuit diagrams illustrating examples of a semiconductor memory device of FIGS. 1 and 5.

FIGS. 9, 10, 11, 12, 13 and 14 are diagrams illustrating examples of a semiconductor memory device of FIG. 1.

FIGS. 15, 16, 17, 18, 19, 20A, 20B and 21 are perspective views, plan views and cross-sectional view for describing a semiconductor memory device according to example embodiments.

FIG. 22 is a block diagram illustrating a semiconductor memory device according to example embodiments.

FIG. 23 is a block diagram illustrating a memory system according to example embodiments.

### DETAILED DESCRIPTION OF THE EMBODIMENTS

Various example embodiments will be described more fully with reference to the accompanying drawings. The present invention may, however, be embodied in many different forms and should not be construed as limited to the embodiments set forth herein. Like reference numerals refer to like elements throughout this application.

It will be understood that when an element is referred to as being “connected” to or “on” another element, it can be directly connected or coupled to or on the other element or intervening elements may be present. As used herein, components described as being “electrically connected” are configured such that an electrical signal can be transferred from one component to the other (although such electrical signal may be attenuated in strength as it is transferred and may be selectively transferred). Components described as “selectively and electrically connected” refer to components that are electrically connected through at least one active element when it is in an “on”state to allow electrical signals to pass therethrough.

Items described in the singular herein may be provided in plural. Thus, the description of a single item that is provided in plural should be understood to be applicable to the remaining plurality of items unless context indicates otherwise.

It will be understood that, although the terms first, second, third etc. may be used herein to describe various elements or components, these elements or components should not be limited by these terms. Unless the context indicates otherwise, these terms are only used to distinguish one element or component from another element or component. Thus, a first element or component discussed below in one section of the specification could be termed as a second element or component in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Hereinafter, in the specification (and not necessarily in the claims), a vertical direction that is substantially perpendicular to an upper surface of a substrate may be a first direction D1, and two intersecting directions among horizontal directions, which extend across the upper surface of the substrate, may be second and third directions D2 and D3, respectively. For example, the second and third directions D2 and D3 may be substantially perpendicular to each other. Each of the first, second and third directions D1, D2 and D3 may include both the direction shown in the drawings and its inverse.

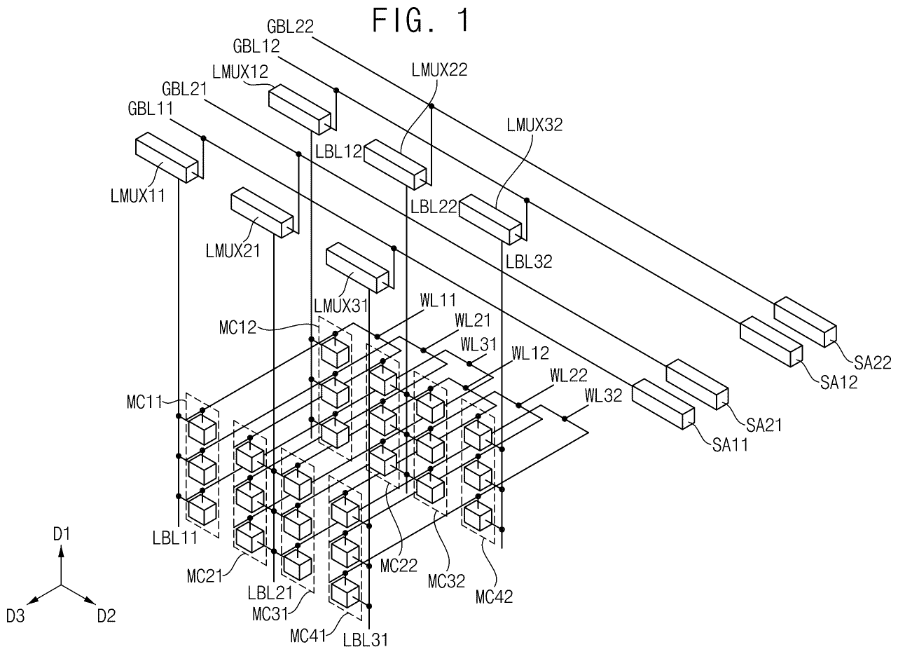

FIG. 1 is a perspective view of a semiconductor memory device according to example embodiments.

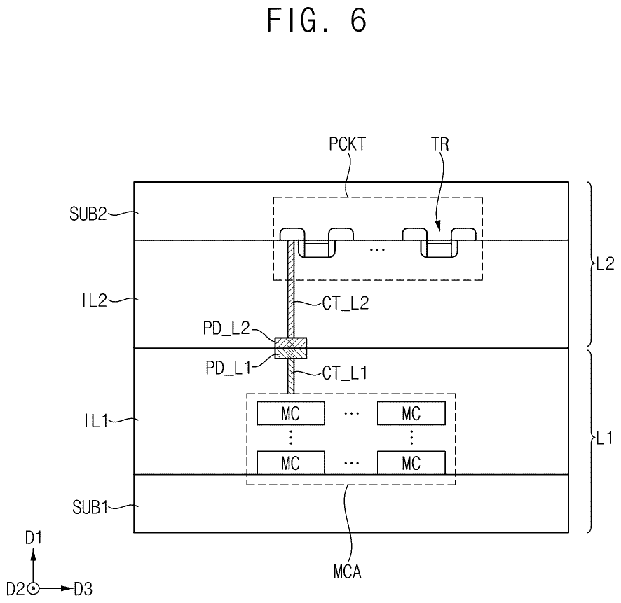

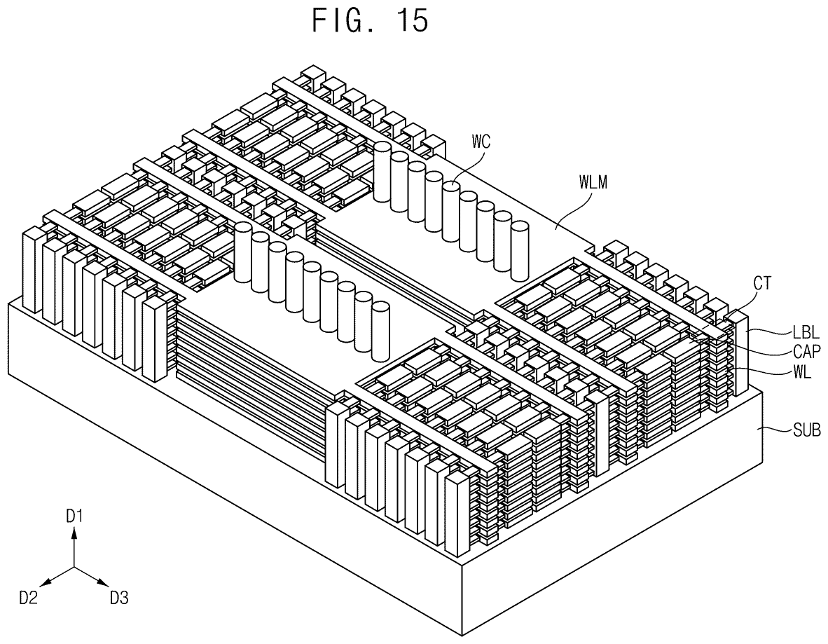

Referring to FIG. 1, a portion of a memory cell array of a semiconductor memory device is illustrated, and a portion of a peripheral circuit connected to the portion of the memory cell array is illustrated. For example, the memory cell array (or the portion thereof) may be formed, disposed and/or arranged on the substrate (e.g., a first substrate SUB1 in FIG. 6 and/or a substrate SUB in FIG. 15).

The semiconductor memory device includes a plurality of memory cells MC11, MC21, MC31, MC41, MC12, MC22, MC32 and MC42, a plurality of local bitlines LBL11, LBL21, LBL31, LBL12, LBL22 and LBL32, a plurality of wordlines WL11, WL21, WL31, WL12, WL22 and WL32, a plurality of global bitlines GBL11, GBL21, GBL12 and GBL22, a plurality of local bitline multiplexers LMUX11, LMUX21, LMUX31, LMUX12, LMUX22 and LMUX32, and a plurality of sense amplifiers SA11, SA21, SA12 and SA22. A bitline structure in which a global bitline is selectively connected to a local bitline through a local bitline multiplexer, and a sense amplifier is connected to the global bitline for performing a sensing operation on the local bitline may be called a hierarchical bitline structure to distinguish from a bitline structure in which the sense amplifier is directly connected to the local bitline.

For example, the plurality of memory cells MC11, MC21, MC31, MC41, MC12, MC22, MC32 and MC42, the plurality of local bitlines LBL11, LBL21, LBL31, LBL12, LBL22 and LBL32, and the plurality of wordlines WL11, WL21, WL31, WL12, WL22 and WL32 may be included in the memory cell array (or the portion thereof), and the plurality of global bitlines GBL11, GBL21, GBL12 and GBL22, and the plurality of local bitline multiplexers LMUX11, LMUX21, LMUX31, LMUX12, LMUX22 and LMUX32 may be included in the memory cell array (or the portion thereof). Alternatively, the plurality of global bitlines GBL11, GBL21, GBL12 and GBL22, and the plurality of local bitline multiplexers LMUX11, LMUX21, LMUX31, LMUX12, LMUX22 and LMUX32 may be included in the peripheral circuit (or the portion thereof). The plurality of sense amplifiers SA11, SA21, SA12 and SA22 may be included in the peripheral circuit (or the portion thereof).

The plurality of memory cells MC11, MC21, MC31, MC41, MC12, MC22, MC32 and MC42 are disposed on the substrate, and are arranged along the first, second and third directions D1, D2 and D3. Unlike a two-dimensional (2D) semiconductor memory device in which memory cells are arranged along the second and third directions D2 and D3, the semiconductor memory device according to example embodiments may be a three-dimensional (3D) semiconductor memory device in which the plurality of memory cells MC11, MC21, MC31, MC41, MC12, MC22, MC32 and MC42 are arranged not only along the second and third directions D2 and D3 but also along the first direction D1.

The plurality of local bitlines LBL11, LBL21, LBL31, LBL12, LBL22 and LBL32 are disposed on the substrate, and are electrically connected to the plurality of memory cells MC11, MC21, MC31, MC41, MC12, MC22, MC32 and MC42. Each of the plurality of local bitlines LBL11, LBL21, LBL31, LBL12, LBL22 and LBL32 extends in the first direction D1. The plurality of local bitlines LBL11, LBL21, LBL31, LBL12, LBL22 and LBL32 may be spaced apart from each other in the second and third directions D2 and D3.

In some example embodiments, some memory cells may be disposed between two local bitlines that are arranged adjacently along the second direction D2. Memory cells that are arranged adjacently along the first direction D1 in which each local bitline extends may be electrically connected to the same local bitline. For example, memory cells that are arranged along the first direction D1 may form one cell string, and each cell string may include memory cells which may be electrically connected to one local bitline based on wordline voltages applied to the wordlines connected to the memory cells. Each memory cell of the cell string may be connected with a wordline extending along the third direction D3, and thus the memory cells at the same level of the cell strings arranged along the third direction D3 may be connected with the same wordline. The cell strings arranged in the third direction D3 may be a cell string row. For example, among the cell strings MC11, MC21, MC31, MC41, MC12, MC22, MC32 and MC42, memory cells MC11 and MC12, memory cells MC21 and MC22, memory cells MC31 and MC32, and memory cells MC41 and MC42 may correspond to the first to fourth cell string rows respectively. In some example embodiments, some memory cells that are arranged adjacently along the second direction D2 may be electrically connected to the same local bitline. For example, two cell strings, which are arranged adjacent in the second direction D2 may share one local bitline, and memory cells of the two cell strings may be electrically connected to the shared local bitline based on wordline voltages applied to wordlines connected to memory cells of the two cell strings. For example, when a wordline of the two cell strings connected is activated, a memory cell of the two cell strings may be electrically connected to the local bitline. The two cell strings sharing one local bitline are connected to two different wordlines. Because only one of the two wordlines is activated at a time, the two cell strings may be selectively connected to the shared local bitline without confliction.

For example, the memory cells MC11 and MC21 may be disposed between the local bitlines LBL11 and LBL21 that are adjacent to each other in the second direction D2. Among the memory cells MC11 and MC21, the memory cells MC11 that are arranged along the first direction D1 may be and electrically connected to the same local bitline (e.g., the local bitline LBL11), and the memory cells MC21 that are arranged along the first direction D1 may be electrically connected to the same local bitline (e.g., the local bitline LBL21). The memory cells MC11 and the memory cells MC21 may not share any local bitline.

For example, the memory cells MC31 and MC41 may be disposed between the local bitlines LBL21 and LBL31 that are adjacent to each other in the second direction D2. Among the memory cells MC31 and MC41, the memory cells MC31 that are arranged along the first direction D1 may be electrically connected to the same local bitline (e.g., the local bitline LBL21), and the memory cells MC41 that are arranged along the first direction D1 may be electrically connected to the same local bitline (e.g., the local bitline LBL31). The memory cells MC31 and the memory cells MC41 may not share any local bitline. For example, the memory cells MC21 and MC31 may share the local bitline LBL21.

Similarly, the memory cells MC12 and MC22 may be disposed between the local bitlines LBL12 and LBL22, the memory cells MC12 may be electrically connected to the local bitline LBL12, and the memory cells MC22 may be electrically connected to the local bitline LBL22. The memory cells MC32 and MC42 may be disposed between the local bitlines LBL22 and LBL32, the memory cells MC32 may be electrically connected to the local bitline LBL21, and the memory cells MC42 may be electrically connected to the local bitline LBL32. The memory cells MC12 and the memory cells MC22 may not share any local bitline, the memory cells MC32 and the memory cells MC32 may not share any local bitline, and the memory cells MC22 and MC32 may share the local bitline LBL22.

The plurality of wordlines WL11, WL21, WL31, WL12, WL22 and WL32 are disposed on the substrate, and are electrically connected to the plurality of memory cells MC11, MC21, MC31, MC41, MC12, MC22, MC32 and MC42. Each of the plurality of wordlines WL11, WL21, WL31, WL12, WL22 and WL32 extends in the third direction D3. The plurality of wordlines WL11, WL21, WL31, WL12, WL22 and WL32 may be spaced apart from each other in the first and second directions D1 and D2. Each of the plurality of wordlines may be electrically connected to memory cells of corresponding two adjacent cell string rows. For example, the wordlines WL11, WL21, and WL31 may be connected to the memory cells of the first cell string row MC11 and MC12 and the second cell string row MC21 and MC22. The wordlines WL12, WL22, and WL32 may be connected to the memory cells of the third cell string row of MC31 and MC32 and the fourth cell string row MC41 and MC42. Each of the wordlines WL11, WL21, WL31, WL12, WL22, and WL32 may be a merged wordline which is implemented by merging two wordlines connected to two adjacent cell string rows.

In some example embodiments, the plurality of memory cells MC11, MC21, MC31, MC41, MC12, MC22, MC32 and MC42 may be disposed at a plurality of different levels along the first direction D1, and memory cells that are disposed at the same level and arranged along the third direction D3 (i.e., along which each wordline extends) may be electrically connected to the same wordline. For example, memory cells that are arranged along the third direction D3 at the same level may form one cell row, and memory cells of the cell row may be electrically connected to one wordline. In some example embodiments, some of memory cells that are disposed at the same level and arranged adjacently along the second direction D2 may be electrically connected to the same wordline. For example, memory cells in two cell rows, which are disposed at the same level, adjacent to each other in the second direction D2, and connected to different local bitlines, may be electrically connected to the same wordline and may share the same wordline.

For example, a first memory cell among the memory cells MC11 and a second memory cell among the memory cells MC12 that are adjacent to each other in the third direction D3, and disposed at the same level may be electrically connected to the same wordline among the wordlines WL11, WL21 and WL31. In addition, the first memory cell among the memory cells MC11 and a third memory cell among the memory cells MC21 that are adjacent to each other in the second direction D2, and the second memory cell among the memory cells MC12 and a fourth memory cell among the memory cells MC22 that are adjacent to each other in the second direction D2, and disposed at the same level may be electrically connected to the same wordline among the wordlines WL11, WL21 and WL31. For example, each memory cell of the memory cells MC11, MC12, MC21 and MC22, disposed at the uppermost level (or top level) may be electrically connected to the wordline WL11. Each memory cell of the memory cells MC11, MC12, MC21 and MC22 disposed at the middle level may be electrically connected to the wordline WL21. Each memory cell of the memory cells MC11, MC12, MC21 and MC22 disposed at the lowermost level (or bottom level) may be electrically connected to the wordline WL31. A merged wordline may be connected to the memory cells of the memory cells MC11 and MC12 and the memory cells MC21 and MC22 disposed at the same level.

Similarly, a single wordline, among the wordlines WL12, WL22 and WL32, may be electrically connected to cell rows of the memory cells MC31 and MC32 that are adjacent in the third direction D3, and to cell rows of the memory cells MC41 and MC42 that are adjacent in the second direction D2. For example, each memory cell of the memory cells MC31, MC32, MC41 and MC42 disposed at the uppermost level may be electrically connected to the wordline WL12. Each memory cell of the memory cells MC31, MC32, MC41 and MC42 disposed at the middle level may be electrically connected to the wordline WL22, and each memory cell of the memory cells MC31, MC32, MC41 and MC42 disposed at the lowermost level may be electrically connected to the wordline WL32.

As described above, the semiconductor memory device may be implemented with a wordline merging structure in which two adjacent wordlines are merged into one wordline, and thus the semiconductor memory device may have improved performance and characteristics.

The plurality of global bitlines GBL11, GBL21, GBL12 and GBL22 are disposed on the plurality of local bitlines LBL11, LBL21, LBL31, LBL12, LBL22 and LBL32. For example, each of the plurality of global bitlines GBL11, GBL21, GBL12 and GBL22 may extend in the second direction D2.

Each of the plurality of global bitlines GBL11, GBL21, GBL12 and GBL22 are selectively connected to one of the plurality of local bitlines LBL11, LBL21, LBL31, LBL12, LBL22 and LBL32. For example, the global bitline GBL11 may be selectively connected to one of the local bitlines LBL11 and LBL31, and the global bitline GBL21 may be selectively connected to the local bitline LBL21. Similarly, the global bitline GBL12 may be selectively connected to one of the local bitlines LBL12 and LBL32, and the global bitline GBL22 may be selectively connected to the local bitline LBL22.

The plurality of local bitline multiplexers LMUX11, LMUX21, LMUX31, LMUX12, LMUX22 and LMUX32 control electrical connections between the plurality of local bitlines LBL11, LBL21, LBL31, LBL12, LBL22 and LBL32 and the plurality of global bitlines GBL11, GBL21, GBL12 and GBL22.

For example, the local bitline multiplexer LMUX11 may control the electrical connection between the local bitline LBL11 and the global bitline GBL11, the local bitline multiplexer LMUX21 may control the electrical connection between the local bitline LBL21 and the global bitline GBL21, and the local bitline multiplexer LMUX31 may control the electrical connection between the local bitline LBL31 and the global bitline GBL11. Similarly, the local bitline multiplexer LMUX12 may control the electrical connection between the local bitline LBL12 and the global bitline GBL12, the local bitline multiplexer LMUX22 may control the electrical connection between the local bitline LBL22 and the global bitline GBL22, and the local bitline multiplexer LMUX32 may control the electrical connection between the local bitline LBL32 and the global bitline GBL12.

The plurality of sense amplifiers SA11, SA21, SA12 and SA22 may be electrically connected to the plurality of global bitlines GBL11, GBL21, GBL12 and GBL22, and each sense amplifier may perform sensing operation on a memory cell connected to a corresponding local bitline among the plurality of local bitlines LBL11, LBL21, LBL31, LBL12, LBL22 and LBL32 and a corresponding global bitline among the plurality of global bitlines GBL11, GBL21, GBL12 and GBL22. The sensing operation may include detecting and amplifying small voltage variations resulting from charge sharing between a memory cell capacitor and the local and global bitlines connected to the memory cell.

For example, the sense amplifier SA11, electrically connected to the global bitline GBL11, may perform a sensing operation on the memory cell electrically connected to the local bitline LBL11 and the global bitline GBL11 when the local bitline LBL11 and the global bitline GBL11 are electrically connected through the local bitline multiplexer LMUX11, and may perform a sensing operation on the memory cell electrically connected to the local bitline LBL31 and the global bitline GBL11 when the local bitline LBL31 and the global bitline GBL11 are electrically connected through the local bitline multiplexer LMUX31. For example, the sense amplifier SA21, electrically connected to the global bitline GBL21, and may perform a sensing operation on the memory cell electrically connected to the local bitline LBL21 and the global bitline GBL21 when the local bitline LBL21 and the global bitline GBL21 are electrically connected through the local bitline multiplexer LMUX21.

Similarly, the sense amplifier SA12, electrically connected to the global bitline GBL12, may perform a sensing operation on the memory cell electrically connected to the local bitline LBL12 and the global bitline GBL12 when the local bitline LBL12 and the global bitline GBL12 are electrically connected through the local bitline multiplexer LMUX12, and may perform a sensing operation on the memory cell electrically connected to the local bitline LBL32 and the global bitline GBL12 when the local bitline LBL32 and the global bitline GBL12 are electrically connected through the local bitline multiplexer LMUX32. For example, the sense amplifier SA22, electrically connected to the global bitline GBL22, may perform a sensing operation on the memory cell connected to the local bitline LBL22 and the global bitline GBL22 when the local bitline LBL22 and the global bitline GBL22 are electrically connected through the local bitline multiplexer LMUX22.

Although FIG. 1 illustrates an example of the semiconductor memory device that includes specific numbers of memory cells, local bitlines, wordlines, global bitlines, local bitline multiplexers and sense amplifiers, example embodiments are not limited thereto.

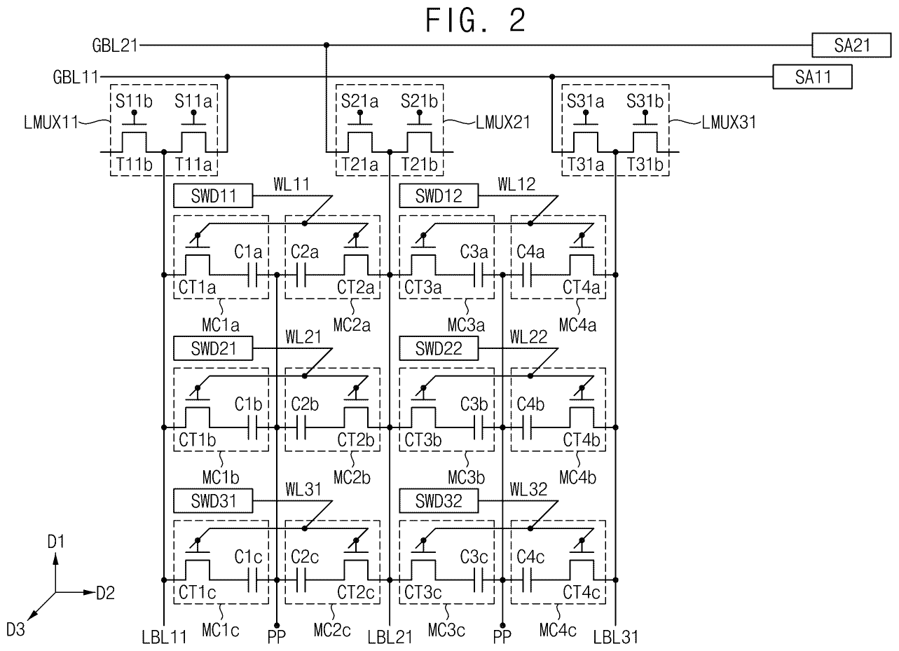

FIG. 2 is a circuit diagram illustrating an example of a semiconductor memory device of FIG. 1.

Referring to FIG. 2, an example of components that are connected to the local bitlines LBL11, LBL21 and LBL31 and the global bitlines GBL11 and GBL21 in the semiconductor memory device of FIG. 1 is illustrated. The descriptions repeated with or overlapping with descriptions of FIG. 1 will be omitted for brevity.

Each memory cell may include a cell transistor and a capacitor, and may be connected to a wordline and a local bitline. For example, each of memory cells MC1a, MC1b, MC1c, MC2a, MC2b, MC2c, MC3a, MC3b, MC3c, MC4a, MC4b and MC4c may include one of cell transistors CT1a, CT1b, CT1c, CT2a, CT2b, CT2c, CT3a, CT3b, CT3c, CT4a, CT4b and CT4c and one of capacitors (or cell capacitors) C1a, C1b, C1c, C2a, C2b, C2c, C3a, C3b, C3c, C4a, C4b and C4c, and may be connected to one of the local bitlines LBL11, LBL21 and LBL31 and one of the wordlines WL11, WL21, WL31, WL12, WL22 and WL32. The semiconductor memory device may be a dynamic random access memory (DRAM) device, and each memory cell may be a DRAM cell with a (one-transistor-one-capacitor) 1T-1C structure including one cell transistor and one capacitor.

Each of the cell transistors CT1a, CT1b, CT1c, CT2a, CT2b, CT2c, CT3a, CT3b, CT3c, CT4a, CT4b and CT4c may include a gate electrode that is connected to one of the wordlines WL11, WL21, WL31, WL12, WL22 and WL32, a first source/drain layer that is connected to one of the local bitlines LBL11, LBL21 and LBL31, and a second source/drain layer that is connected to one of the capacitors C1a, C1b, C1c, C2a, C2b, C2c, C3a, C3b, C3c, C4a, C4b and C4c. The capacitors C1a, C1b, C1c, C2a, C2b, C2c, C3a, C3b, C3c, C4a, C4b and C4c may be commonly connected to a plate (or plate electrode) PP.

For example, the memory cell MC1a may include the cell transistor CT1a and the capacitor C1a, the cell transistor CT1a may have a gate electrode connected to the wordline WL11 and may be connected between the local bitline LBL11 and the capacitor C1a, and the capacitor C1a may be connected between the cell transistor CT1a and the plate PP. Similarly, the memory cell MC1b may include the cell transistor CT1b and the capacitor C1b, and may be connected to the wordline WL21 and the local bitline LBL11. The memory cell MC1c may include the cell transistor CT1c and the capacitor C1c, and may be connected to the wordline WL31 and the local bitline LBL11. The memory cells MC1a, MC1b and MC1c may correspond to the memory cells MC11 in FIG. 1.

For example, the memory cell MC2a may include the cell transistor CT2a and the capacitor C2a, and may be connected to the wordline WL11 and the local bitline LBL21. The memory cell MC2b may include the cell transistor CT2b and the capacitor C2b, and may be connected to the wordline WL21 and the local bitline LBL21. The memory cell MC2c may include the cell transistor CT2c and the capacitor C2c, and may be connected to the wordline WL31 and the local bitline LBL21. The memory cells MC2a, MC2b and MC2c may correspond to the memory cells MC21 in FIG. 1.

Similarly, the memory cells MC3a, MC3b and MC3c may include the cell transistors CT3a, CT3b and CT3c and the capacitors C3a, C3b and C3c, may be connected to the wordlines WL12, WL22 and WL32 and the local bitline LBL21, and may correspond to the memory cells MC31 in FIG. 1. The memory cells MC4a, MC4b and MC4c may include the cell transistors CT4a, CT4b and CT4c and the capacitors C4a, C4b and C4c, may be connected to the wordlines WL12, WL22 and WL32 and the local bitline LBL31, and may correspond to the memory cells MC41 in FIG. 1.

As described with reference to FIG. 1, wordlines connected to the memory cells MC1a and MC2a may be merged to form one wordline WL11, wordlines connected to memory cells MC1b and MC2b may be merged to form one wordline WL21, and wordlines connected to memory cells MC1c and MC2c may be merged to form one wordline WL31. Similarly, wordlines connected to the memory cells MC3a and MC4a may be merged to form one wordline WL12, wordlines connected to the memory cells MC3b and MC4b may be merged to form one wordline WL22, and wordlines connected to the memory cells MC3c and MC4c may be merged to form one wordline WL32.

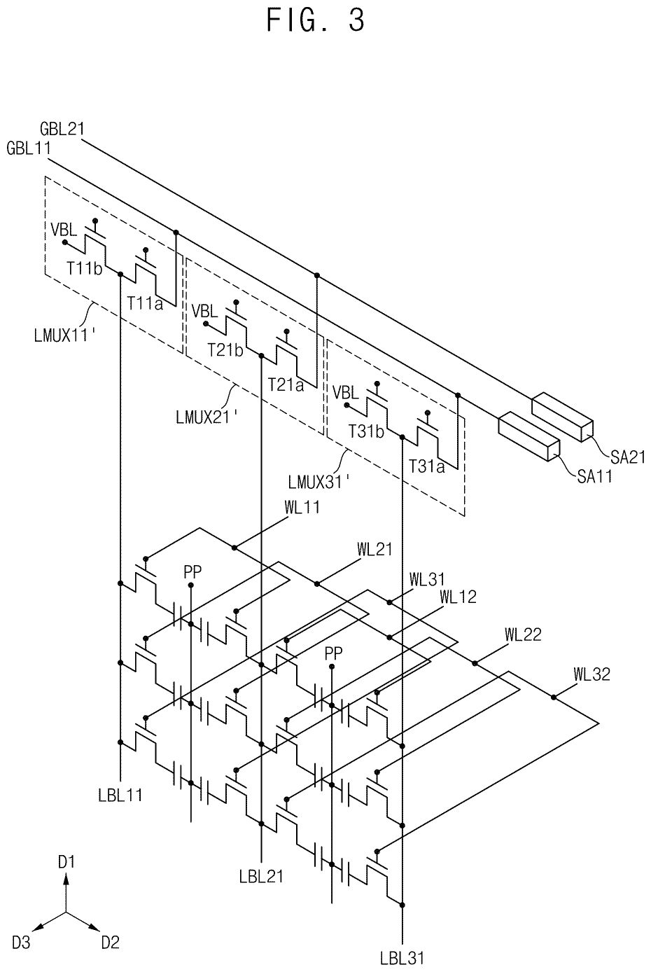

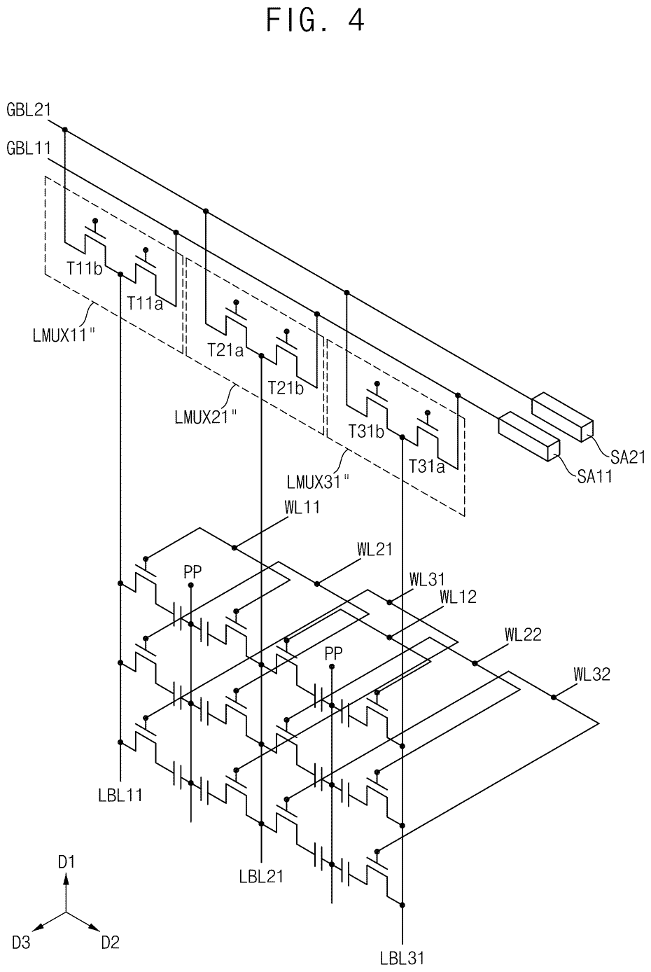

Each of the local bitline multiplexers LMUX11, LMUX21 and LMUX31 may include two transistors. Among the two transistors, one transistor may be connected between one of the local bitlines LBL11, LBL21 and LBL31 and one of the global bitlines GBL11 and GBL21, and the other transistor may be connected between one of the local bitlines LBL11, LBL21 and LBL31 and a precharge voltage VBL. Alternatively, the other transistor may be connected between one of the local bitlines LBL11, LBL21 and LBL31 and other one of the global bitlines GBL11 and GBL21. In some example embodiments, as will be described with reference to FIGS. 3 and 4, the connection of the other transistor may be changed.

For example, the local bitline multiplexer LMUX11 may include transistors T11a and T11b. The transistor T11a may be connected between the local bitline LBL11 and the global bitline GBL11, and may have a gate electrode receiving a control signal S11a. The transistor T11b may be connected between the local bitline LBL11 and the precharge voltage VBL, and may have a gate electrode receiving a control signal S11b. Alternatively, the transistor T11b may be connected between the local bitline LBL11 and the global bitline GBL21. The transistors T11a and T11b may be n-type metal oxide semiconductor (NMOS) transistors, but example embodiments are not limited thereto.

Similarly, the local bitline multiplexer LMUX21 may include a transistor T21a that is connected between the local bitline LBL21 and the global bitline GBL21 and has a gate electrode receiving a control signal S21a, and may include a transistor T21b that is connected between the local bitline LBL21 and the precharge voltage VBL and has a gate electrode receiving a control signal S21b. Alternatively, the transistor T21b may be connected between the local bitline LBL21 and the global bitline GBL11. The local bitline multiplexer LMUX31 may include a transistor T31a that is connected between the local bitline LBL31 and the global bitline GBL11 and has a gate electrode receiving a control signal S31a, and may include a transistor T31b that is connected between the local bitline LBL31 and the precharge voltage VBL and has a gate electrode receiving a control signal S31b. Alternatively, the transistor T31b may be connected between the local bitline LBL31, and the global bitline GBL21.

In some example embodiments, the semiconductor memory device may further include a plurality of sub-wordline drivers SWD11, SWD21, SWD31, SWD12, SWD22 and SWD32. The plurality of sub-wordline drivers SWD11, SWD21, SWD31, SWD12, SWD22 and SWD32 may be electrically connected to the plurality of wordlines WL11, WL21, WL31, WL12, WL22 and WL32, and may drive the plurality of wordlines WL11, WL21, WL31, WL12, WL22 and WL32. For example, the plurality of sub-wordline drivers SWD11, SWD21, SWD31, SWD12, SWD22 and SWD32 may be included in the memory cell array (or the portion thereof) and/or the peripheral circuit (or the portion thereof).

Although not illustrated in detail, components that are connected to the local bitlines LBL12, LBL22 and LBL32 and the global bitlines GBL12 and GBL22, e.g., the memory cells MC12, MC22, MC32 and MC42 and the local bitline multiplexers LMUX12, LMUX22 and LMUX32 may also be implemented similarly to those described with reference to FIG. 2.

According to example embodiments, a merged wordline implemented by merging two adjacent wordlines may be connected to the memory cells at the same level of two adjacent cell string rows (e.g., two adjacent cell rows), which do not share a local bitline. In addition, each local bitline is connected to a local bitline multiplexer that controls the electrical connection between the local bitline and the global bitline, and a sensing operation may be performed on a memory cell connected to the local bitline by the sense amplifier connected to the global bitline. When compared with a case in which sense amplifiers are directly connected with the local bitlines, the number of sense amplifiers may be reduced and the layout size restriction of each sense amplifier may be released because multiple local bitlines are connected to a single global line through a plurality of local bitline multiplexers, and layout size of each sense amplifier is not limited to the size of the memory cell, thereby improving electrical characteristics and reliability of the semiconductor memory device. Because the local bitline and the global bitline may be selectively connected and disconnected using the local bitline multiplexer, the increase of the capacitance (e.g., CBL) due to the hierarchical bitline structure may be limited and the sensing margin may be maintained.

FIGS. 3 and 4 are perspective views of examples of a semiconductor memory device of FIG. 1.

Referring to FIG. 3, an example of connections of the transistors T11b, T21b and T31b is illustrated. The descriptions repeated with or overlapping with descriptions of FIGS. 1 and 2 will be omitted for brevity.

As with those described with reference to FIG. 2, a local bitline multiplexer LMUX11′ may include the transistors T11a and T11b, a local bitline multiplexer LMUX21′ may include the transistors T21a and T21b, and a local bitline multiplexer LMUX31′ may include the transistors T31a and T31b.

In an example of FIG. 3, each of the transistors T11b, T21b and T31b may be connected between one of the local bitlines LBL11, LBL21 and LBL31 and a precharge voltage VBL. For example, the transistor T11b may be connected between the local bitline LBL11 and the precharge voltage VBL, the transistor T21b may be connected between the local bitline LBL21 and the precharge voltage VBL, and the transistor T31b may be connected between the local bitline LBL31 and the precharge voltage VBL.

As described above, the transistors T11b, T21b and T31b that are connected to the precharge voltage VBL may be keeper transistors, and the transistors T11a, T21a and T31a that are connected to the global bitlines GBL11 and GBL21 may be selection transistors. FIG. 3 illustrates an example where each local bitline multiplexer includes one keeper transistor and one selection transistor.

Referring to FIG. 4, an example of connections of the transistors T11b, T21b and T31b is illustrated. The descriptions repeated with or overlapping with descriptions of FIGS. 1, 2 and 3 will be omitted for brevity.

As with those described with reference to FIG. 2, a local bitline multiplexer LMUX11″ may include the transistors T11a and T11b, a local bitline multiplexer LMUX21″ may include the transistors T21a and T21b, and a local bitline multiplexer LMUX31″ may include the transistors T31a and T31b.

In an example of FIG. 4, each of the transistors T11b, T21b and T31b may be connected between one of the local bitlines LBL11, LBL21, LBL31 and another one of the global bitlines GBL11 and GBL21. For example, the transistor T11b may be connected between the local bitline LBL11 and the global bitline GBL21 that is different from the global bitline GBL11 to which the transistor T11a is connected, the transistor T21b may be connected between the local bitline LBL21 and the global bitline GBL11 that is different from the global bitline GBL21 to which the transistor T21a is connected, and the transistor T31b may be connected between the local bitline LBL31 and the global bitline GBL21 that is different from the global bitline GBL1 to which the transistor T31a is connected.

FIG. 4 illustrates an example where each local bitline multiplexer includes two selection transistors.

In some example embodiments, the semiconductor memory device according to example embodiments may be implemented by combining the examples of FIGS. 3 and 4. For example, some local bitline multiplexers may be implemented based on the example of FIG. 3, and other local bitline multiplexers may be implemented based on the example of FIG. 4.

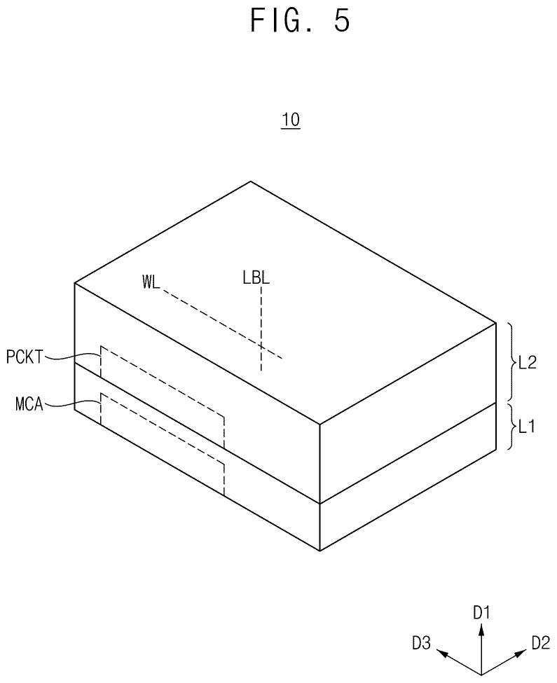

FIG. 5 is a perspective view of a semiconductor memory device according to example embodiments. FIG. 6 is a cross-sectional view of a semiconductor memory device of FIG. 5.

Referring to FIGS. 5 and 6, a semiconductor memory device 10 includes a first semiconductor layer L1 and a second semiconductor layer L2.

The first semiconductor layer L1 and the second semiconductor layer L2 are disposed or stacked in the first direction D1. For example, the second semiconductor layer L2 may be stacked on the first semiconductor layer L1 in the first direction D1, and the first semiconductor layer L1 may be disposed under (e.g., directly beneath or indirectly beneath) the second semiconductor layer L2 in the first direction D1. However, example embodiments are not limited thereto. For example, the semiconductor memory device 10 may be flipped during the manufacturing process, resulting in the first semiconductor layer L1 being stacked on the second semiconductor layer L2 in the first direction D1.

The first semiconductor layer L1 may include a first substrate SUB1, a memory cell array MCA, a plurality of wordlines WL and a plurality of local bitlines LBL. The first semiconductor layer L1 may further include a first bonding pad PD_L1, a first contact CT_L1 and a first insulating layer IL1. The first semiconductor layer L1 may be a memory cell region (MCR) and/or a cell wafer.

The first substrate SUB1 may be a supporting layer that supports components (or elements) of the first semiconductor layer L1. For example, the first substrate SUB1 may be a silicon substrate, and may be a base substrate. The first insulating layer IL1 may cover the components of the first semiconductor layer L1. The first insulating layer IL1 may include a plurality of insulating layers.

The memory cell array MCA, the plurality of wordlines WL and the plurality of local bitlines LBL may be disposed and/or formed on the first substrate SUB1. For example, each of the plurality of wordlines WL may extend in the third direction D3, and the plurality of wordlines WL may be arranged along the first and second directions D1 and D2. For example, each of the plurality of local bitlines LBL may extend in the first direction D1, and the plurality of local bitlines LBL may be arranged along the second and third directions D2 and D3. For example, the memory cell array MCA may include a plurality of memory cells MC that are arranged along the first, second and third directions D1, D2 and D3, and each of the plurality of memory cells MC may be electrically connected to one of the plurality of wordlines WL and one of the plurality of local bitlines LBL.

The second semiconductor layer L2 may include a second substrate SUB2 and a peripheral circuit PCKT. The second semiconductor layer L2 may further include a second bonding pad PD_L2, a second contact CT_L2 and a second insulating layer IL2. Thus, the second semiconductor layer L2 may be a peripheral circuit region (PCR) and/or a peripheral wafer (or a core wafer).

Like the first substrate SUB1 and the first insulating layer IL1, the second substrate SUB2 may serve as a supporting layer that supports components of the second semiconductor layer L2, and the second insulating layer IL2 may cover the components of the second semiconductor layer L2.

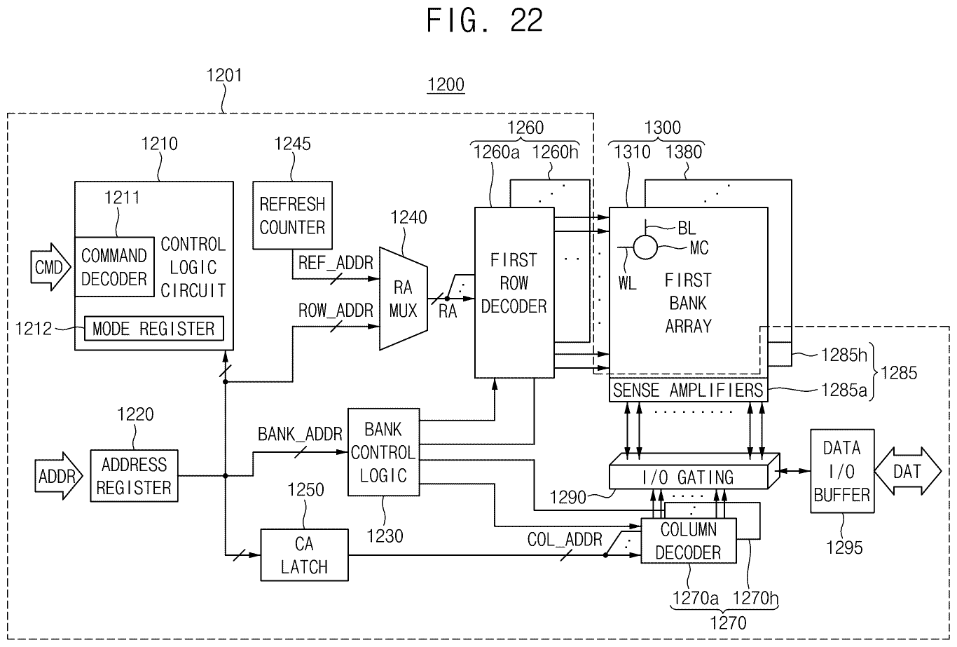

The peripheral circuit PCKT may be disposed and/or formed on the second substrate SUB2. For example, the peripheral circuit PCKT may include a plurality of transistors TR, and various circuits may be formed by the plurality of transistors TR. For example, as will be described with reference to FIG. 22, the peripheral circuit PCKT may include a sense amplifier unit, an input/output gating circuit, etc.

In some example embodiments, the first semiconductor layer L1 and the second semiconductor layer L2 may be manufactured separately, and then the first semiconductor layer L1 and the second semiconductor layer L2 may be connected to each other by a bonding scheme (or method). For example, the bonding scheme may represent a method of electrically and/or physically connecting a bonding metal pattern (e.g., the first bonding pad PD_L1) formed in the first semiconductor layer L1 with a bonding metal pattern (e.g., the second bonding pad PD_L2) formed in the second semiconductor layer L2. For example, the bonding pads PD_L1 and PD_L2 may be formed of copper (Cu), and the bonding scheme may be a Cu—Cu bonding scheme. Alternatively, the bonding pads PD_L1 and PD_L2 may be formed of aluminum (Al) or tungsten (W).

For example, the memory cell array MCA (e.g., the wordlines WL and the local bitlines LBL) of the first semiconductor layer L1 and the peripheral circuit PCKT of the second semiconductor layer L2 may be electrically connected to each other by the first and second bonding pads PD_L1 and PD_L2. More specifically, the memory cell MC and the transistor TR may be electrically connected to each other by the first and second contacts CT_L1 and CT_L2 and the first and second bonding pads PD_L1 and PD_L2. For example, the memory cell MC may be electrically connected to the first contact CT_L1 and the first bonding pad PD_L1, the transistor TR may be electrically connected to the second contact CT_L2 and the second bonding pad PD_L2, and the memory cell MC and the transistor TR may be electrically connected to each other by electrically connecting the first bonding pad PD_L1 with the second bonding pad PD_L2. Although not illustrated in detail, at least one conductive line and/or contact may be further formed to connect the memory cell MC with the first bonding pad PD_L1, and at least one conductive line and/or contact may be further formed to connect the transistor TR with the second bonding pad PD_L2.

However, example embodiments are not limited thereto, and various bonding schemes, such as a hybrid bonding scheme and a dielectric bonding scheme, may be used to electrically and/or physically connect the first semiconductor layer L1 with the second semiconductor layer L2.

The semiconductor memory device 10 according to example embodiments may have or adopt a structure in which the peripheral circuit PCKT and the memory cell array MCA are stacked, e.g., a periphery over cell (POC) structure in which the peripheral circuit PCKT is stacked on the memory cell array MCA. Accordingly, the semiconductor memory device 10 may have a relatively small size when compared with a memory device in which a peripheral circuit and a memory cell array are formed on the same plane. According to an embodiment, the first semiconductor layer L1 may be manufactured by forming the memory cell array MCA on the first substrate SUB1, the second semiconductor layer L2 may be manufactured by forming the peripheral circuit PCKT on the second substrate SUB2, the second semiconductor layer L2 may be flipped, and then the bonding pads PD_L1 and PD_L2 may be connected using the bonding scheme. As a result, the first and second semiconductor layers L1 and L2 may be electrically connected in the first direction D1.

However, example embodiments are not limited thereto, and the semiconductor memory device 10 may have or adopt a cell over periphery (COP) structure in which the memory cell array MCA is formed over the peripheral circuit PCKT.

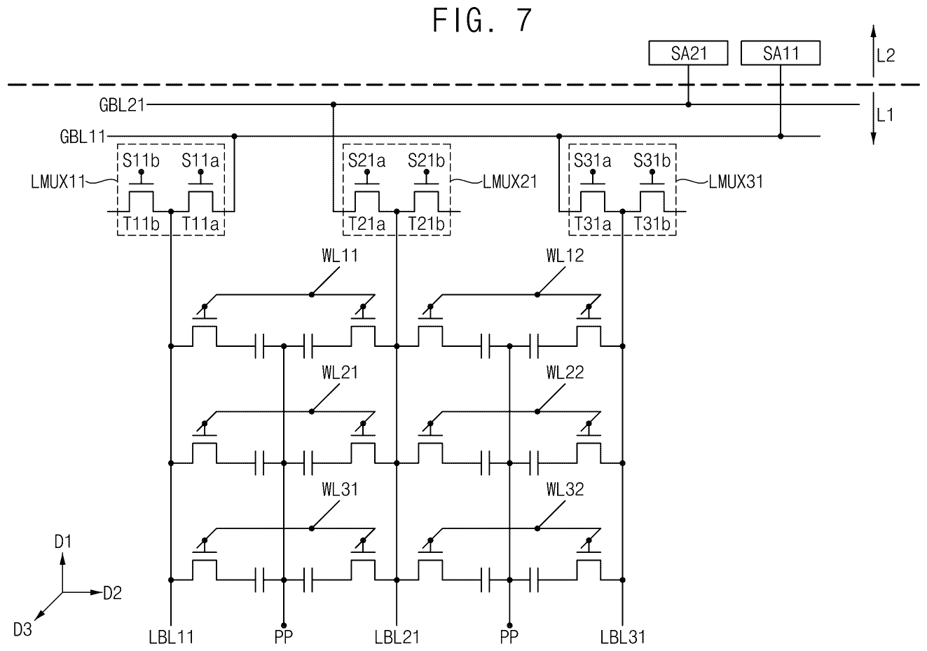

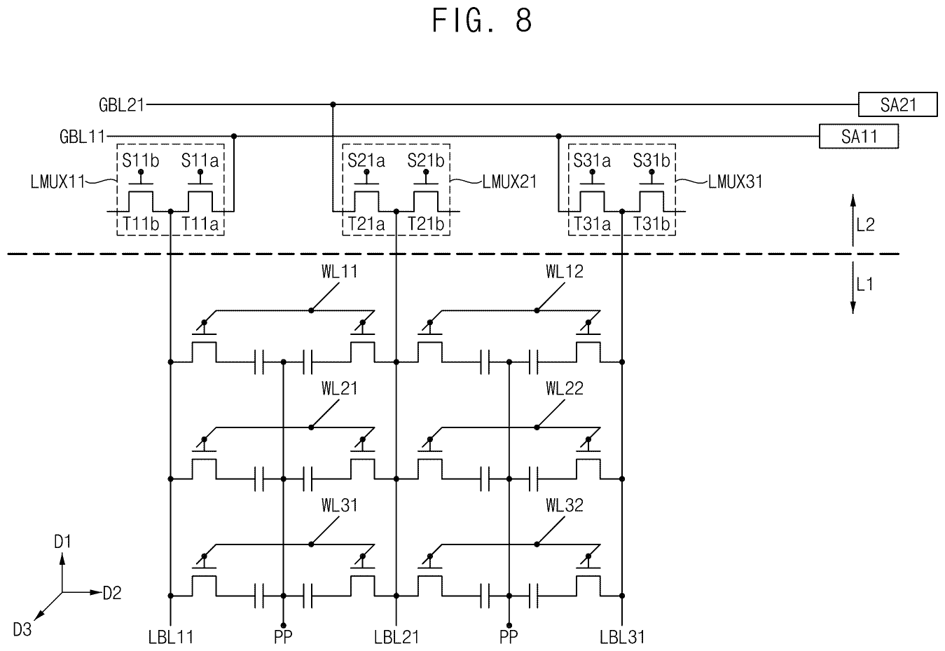

FIGS. 7 and 8 are circuit diagrams illustrating examples of a semiconductor memory device of FIGS. 1 and 5.

Referring to FIG. 7, an example of arrangements of the local bitline multiplexers LMUX11, LMUX21 and LMUX31, the global bitlines GBL11 and GBL21 and the sense amplifiers SA11 and SA21 is illustrated. The descriptions repeated with or overlapping with descriptions of FIGS. 1, 2, 5 and 6 will be omitted for brevity.

The local bitlines LBL11, LBL21 and LBL31, the wordlines WL11, WL21, WL31, WL12, WL22 and WL32, and the memory cells MC1a, MC1b, MC1c, MC2a, MC2b, MC2c, MC3a, MC3b, MC3c, MC4a, MC4b and MC4c may be disposed in the first semiconductor layer L1 (e.g., in the cell wafer), and may be disposed on the first substrate SUB1.

In an example of FIG. 7, the local bitline multiplexers LMUX11, LMUX21 and LMUX31 and the global bitlines GBL11 and GBL21 may be disposed in the first semiconductor layer L1 (e.g., in the cell wafer) together with the memory cells MC1a, MC1b, MC1c, MC2a, MC2b, MC2c, MC3a, MC3b, MC3c, MC4a, MC4b and MC4c, and may be disposed on the first substrate SUB1.

In an example of FIG. 7, the sense amplifiers SA11 and SA21 may be disposed in the second semiconductor layer L2 (e.g., in the peripheral wafer), and may be disposed on the second substrate SUB2 different from the first substrate SUB1. In some example embodiments, when the second semiconductor layer L2 is flipped, and the first and second semiconductor layers L1 and L2 are connected by the bonding scheme, the sense amplifiers SA11 and SA21 may be disposed under the second substrate SUB2.

Referring to FIG. 8, an example of arrangements of the local bitline multiplexers LMUX11, LMUX21 and LMUX31, the global bitlines GBL11 and GBL21 and the sense amplifiers SA11 and SA21 is illustrated. The descriptions repeated with or overlapping with descriptions of FIGS. 1, 2, 5, 6 and 7 will be omitted for brevity.

In an example of FIG. 8, the local bitline multiplexers LMUX11, LMUX21 and LMUX31, the global bitlines GBL11 and GBL21, and the sense amplifiers SA11 and SA21 may be disposed in the second semiconductor layer L2 (e.g., in the peripheral wafer), and may be disposed on the second substrate SUB2. In some example embodiments, when the second semiconductor layer L2 is flipped, and then the first and second semiconductor layers L1 and L2 are connected by the bonding scheme, the local bitline multiplexers LMUX11, LMUX21 and LMUX31, the global bitlines GBL11 and GBL21, and the sense amplifiers SA11 and SA21 may be disposed under the second substrate SUB2.

In some example embodiments, the semiconductor memory device according to example embodiments may be implemented by combining the examples of FIGS. 7 and 8. For example, some regions of the substrate may be implemented based on the example of FIG. 7, and other regions of the substrate may be implemented based on the example of FIG. 8.

In some example embodiments, although not illustrated in detail, the local bitline multiplexers LMUX11, LMUX21 and LMUX31 may be disposed in the first semiconductor layer L1, and the global bitlines GBL11 and GBL21 and the sense amplifiers SA11 and SA21 may be disposed in the second semiconductor layer L2. In some example embodiments, although not illustrated in detail, the global bitlines GBL11 and GBL21 may be disposed in the first semiconductor layer L1, and the local bitline multiplexers LMUX11, LMUX21 and LMUX31 and the sense amplifiers SA11 and SA21 may be disposed in the second semiconductor layer L2.

The semiconductor memory device according to example embodiments may be implemented with the wordline merging structure and the hierarchical bitline structure, and thus the number of sense amplifiers may be reduced. In addition, since the number of sense amplifiers is reduced and the layout size restriction of each sense amplifier is released, bonding defects caused by misalignment may be reduced when the cell wafer and the peripheral wafer are connected to each other by the bonding scheme in the POC structure (or COP structure).

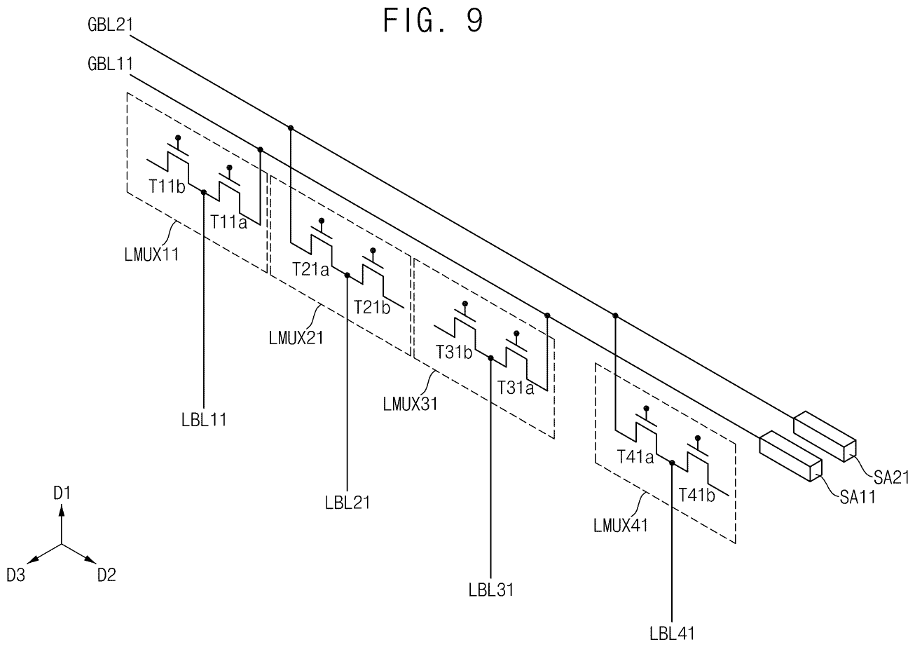

FIGS. 9, 10, 11, 12, 13 and 14 are diagrams illustrating examples of a semiconductor memory device of FIG. 1.

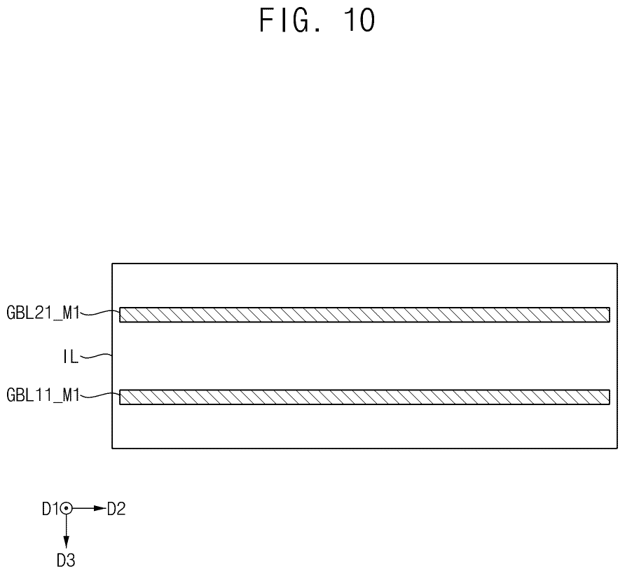

Referring to FIGS. 9 and 10, an example of a structure of the global bitlines GBL11 and GBL21 is illustrated. The descriptions repeated with or overlapping with descriptions of FIGS. 1 and 2 will be omitted for brevity.

The semiconductor memory device may further include a local bitline LBL41 and a local bitline multiplexer LMUX41. The local bitlines LBL31 and LBL41 may be spaced apart from each other in the second direction D2. The local bitline multiplexer LMUX41 may control an electrical connection between the local bitline LBL41 and the global bitline GBL21. The local bitline multiplexer LMUX41 may include a transistor T41a that is connected between the local bitline LBL41 and the global bitline GBL21, and may include a transistor T41b that is connected between the local bitline LBL41 and the precharge voltage VBL. Although not illustrated in detail, similar to described with reference to FIGS. 1 and 2, memory cells stacked along the first direction D1 may be disposed between the local bitlines LBL31 and LBL41, and each of the memory cells stacked along the first direction D1 may be connected to a corresponding wordline among the wordlines connected to the memory cells stacked along the first direction D1.

In an example of FIGS. 9 and 10, the global bitlines GBL11 and GBL21 may be formed with conductive patterns of the same conductive layer, and each of the global bitlines GBL11 and GBL21 may extend in the second direction D2. FIG. 10 is a plan view of the global bitlines GBL11 and GBL21 of FIG. 9.

For example, a first conductive layer may be formed in or on an insulating layer IL, and the first conductive layer may include conductive patterns GBL11_M1 and GBL21_M1. The conductive pattern GBL11_M1 extending in the second direction D2 may correspond to the global bitline GBL11, and the conductive pattern GBL21_M1 extending in the second direction D2 may correspond to the global bitline GBL21.

In addition, the local bitline multiplexers LMUX11, LMUX21, LMUX31 and LMUX41 may be alternately connected to the global bitlines GBL11 and GBL21. For example, the local bitline multiplexer LMUX11 may be connected to the global bitline GBL11 to control the electrical connection between the local bitline LBL11 and the global bitline GBL11, the local bitline multiplexer LMUX21 may be connected to the global bitline GBL21 to control the electrical connection between the local bitline LBL21 and the global bitline GBL21, the local bitline multiplexer LMUX31 may be connected to the global bitline GBL11 to control the electrical connection between the local bitline LBL31 and the global bitline GBL11, and the local bitline multiplexer LMUX41 may be connected to the global bitline GBL21 to control the electrical connection between the local bitline LBL41 and the global bitline GBL21.

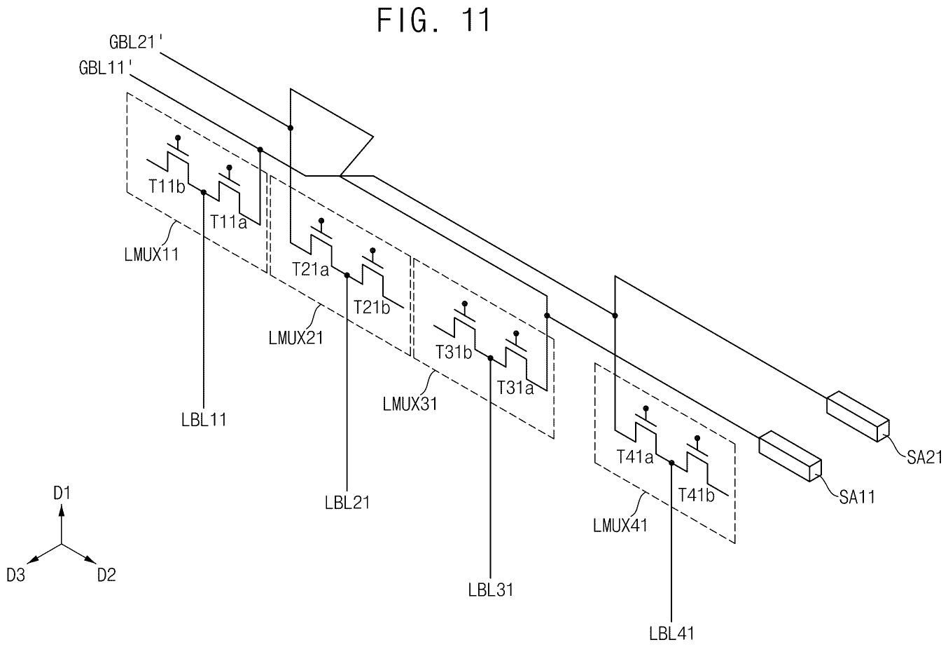

Referring to FIGS. 11, 12, 13 and 14, an example of a structure of the global bitlines GBL11 and GBL21 is illustrated. The descriptions repeated with or overlapping with descriptions of FIGS. 1, 2, 9 and 10 will be omitted for brevity.

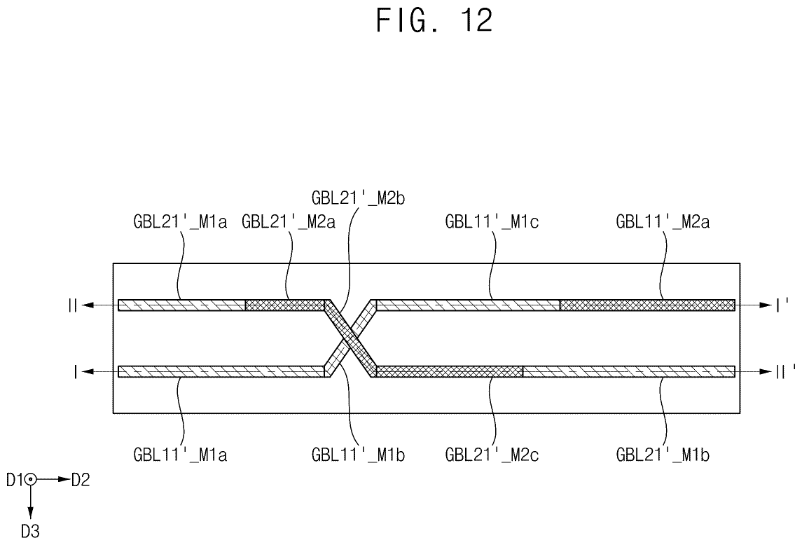

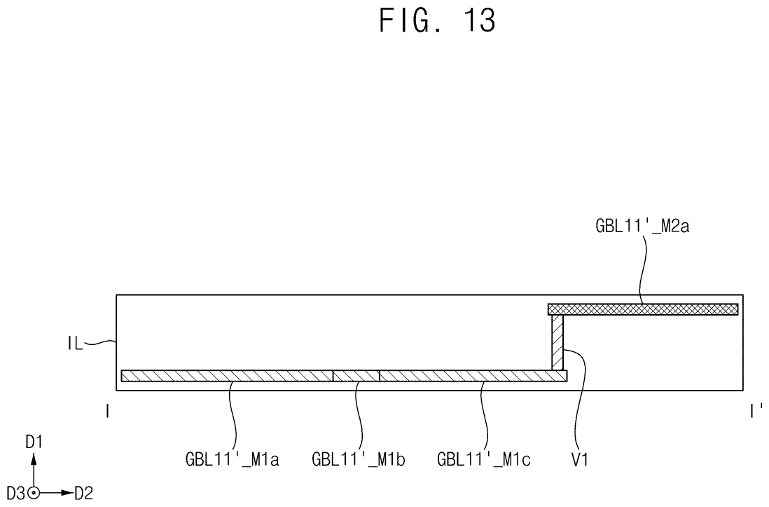

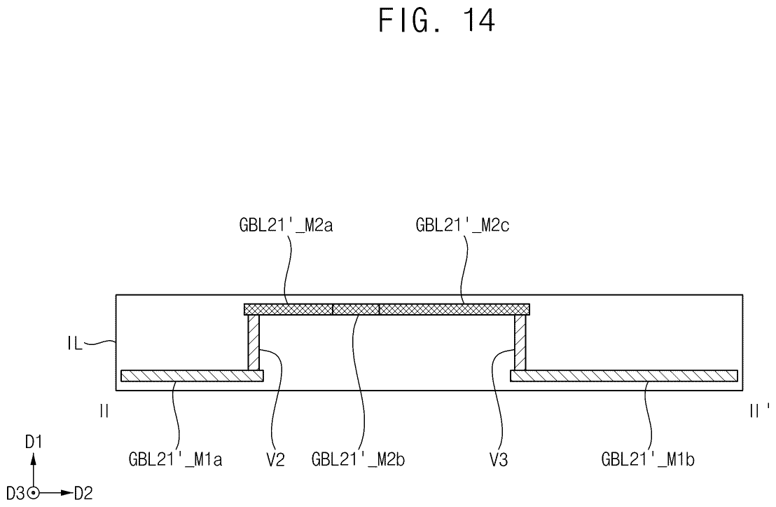

In an example of FIGS. 11, 12, 13 and 14, global bitlines GBL11′ and GBL21′ may be formed with conductive patterns of two conductive layers that are disposed at different levels in the first direction D1. The global bitlines GBL11′ and GBL21′ may be electrically insulated from each other while intersecting in a plan view (or on a plane). For example, the global bitlines GBL11′ and GBL21′ may be implemented with a twisted structure or a cross-coupled structure. FIG. 12 is a plan view of the global bitlines GBL11′ and GBL21′ of FIG. 11, FIG. 13 is a cross-sectional view taken along a line I-I′ in FIG. 12, and FIG. 14 is a cross-sectional view taken along a line II-II′ in FIG. 12.

For example, a first conductive layer and a second conductive layer that are disposed at different levels in the first direction D1 may be formed in or on an insulating layer IL. For example, the insulating layer IL may include a plurality of insulating layers. Among the first and second conductive layers, the first conductive layer that is a lower conductive layer may include conductive patterns GBL11′_M1a, GBL11′_M1b, GBL11′_M1c, GBL21′_M1a and GBL21′_M1b, and the second conductive layer that is an upper conductive layer may include conductive patterns GBL11′_M2a, GBL21′_M2a, GBL21′_M2b and GBL21′_M2c.

The conductive patterns GBL11′_M1a, GBL11′_M1b, GBL11′_M1c and GBL11′_M2a and a vertical via V1 may correspond to the global bitline GBL11′. Each of the conductive patterns GBL11′_M1a, GBL11′_M1c and GBL11′_M2a may extend in the second direction D2, the conductive pattern GBL11′_M1b may extend in a first diagonal direction in a plan view to electrically connect the conductive patterns GBL11′_M1a and GBL11′_M1c with each other, and the conductive patterns GBL11′_M1c and GBL11′_M2a may be electrically connected to each other by the vertical via V1. Although FIG. 12 illustrates that the conductive patterns GBL11′_M1a, GBL11′_M1b and GBL11′_M1c are distinguished from each other, example embodiments are not limited thereto, and the conductive patterns GBL11′_M1a, GBL11′_M1b and GBL11′_M1c may be formed integrally.

The conductive patterns GBL21′_M1a, GBL21′_M2a, GBL21′_M2b, GBL21′_M2c and GBL21′_M1b and vertical vias V2 and V3 may correspond to the global bitline GBL21′. Each of the conductive patterns GBL21′_M1a, GBL21′_M2a, GBL21′_M2c and GBL21′_M1b may extend in the second direction D2, and the conductive pattern GBL21′_M2b may extend in a second diagonal direction in a plan view to electrically connect the conductive patterns GBL21′_M2a and GBL21′_M2c with each other. The conductive patterns GBL21′_M1a and GBL21′_M2a may be electrically connected to each other by the vertical via V2, and the conductive patterns GBL21′_M2c and GBL21′_M1b may be electrically connected to each other by the vertical via V3. Although FIG. 12 illustrates that the conductive patterns GBL21′_M2a, GBL21′_M2b and GBL21′_M2c are distinguished from each other, example embodiments are not limited thereto, and the conductive patterns GBL21′_M2a, GBL21′_M2b and GBL21′_M2c may be formed integrally.

In addition, the local bitline multiplexers LMUX11 and LMUX41 may be connected to the global bitline GBL11′, and the local bitline multiplexers LMUX21 and LMUX31 may be connected to the global bitline GBL21′. The local bitline multiplexer LMUX11 may control the electrical connection between the local bitline LBL11 and the global bit line GBL11′, the local bitline multiplexer LMUX21 may control the electric connection between the local bitline LBL21 and the global bitline GBL21′, the local bitline multiplexer LMUX31 may control the electric connection between the local bitline LBL31 and the global bitline GBL21′, and the local bitline multiplexer LMUX41 may control the electrical connection between the local bitline LBL41 and the global bit line GBL11′.

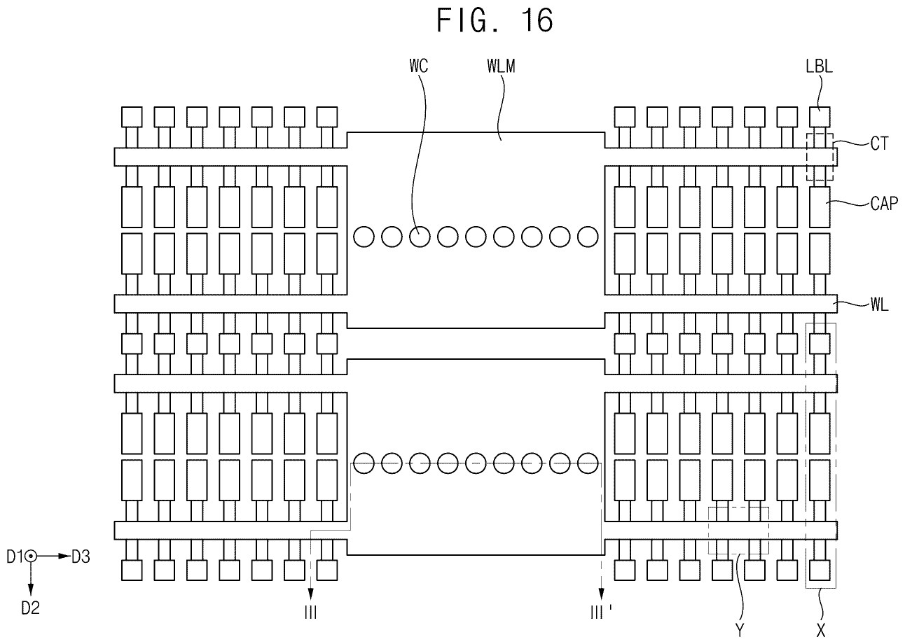

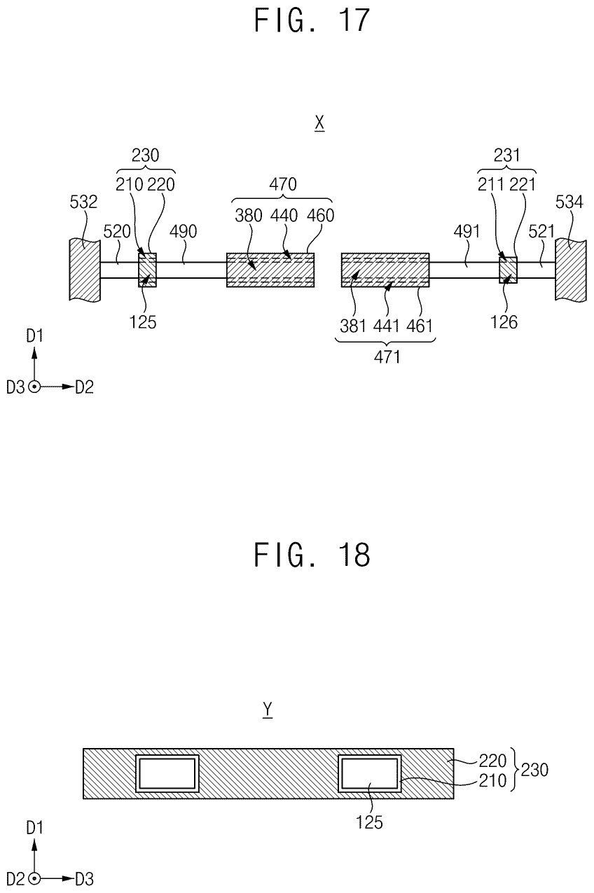

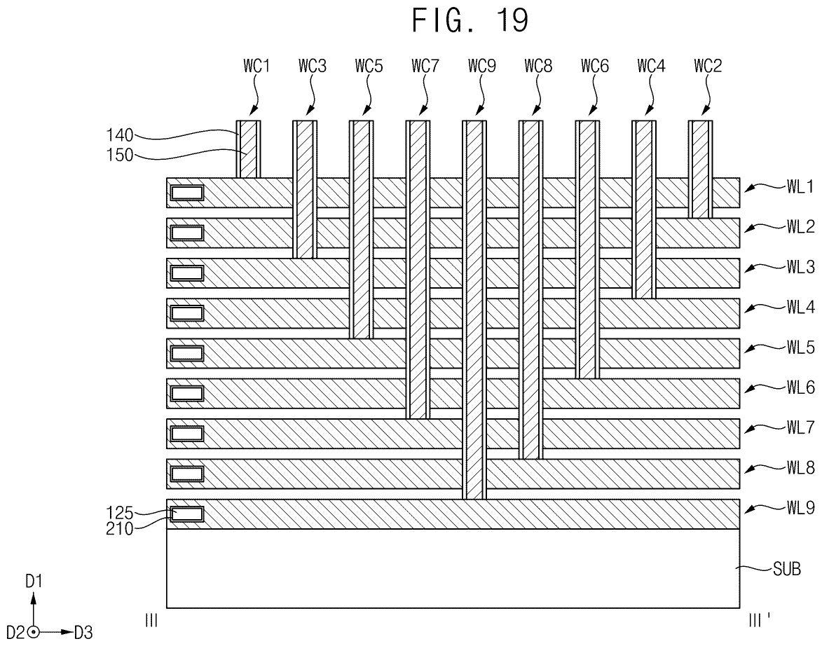

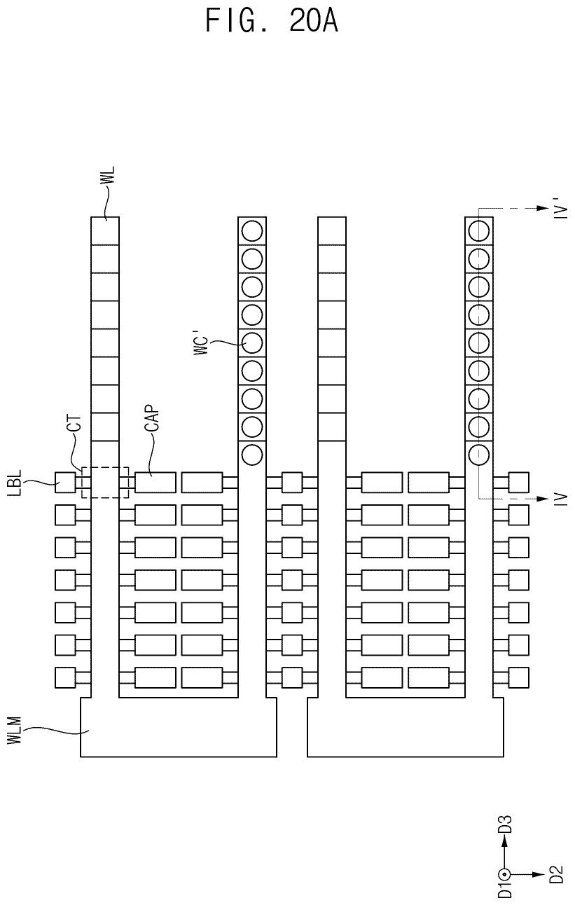

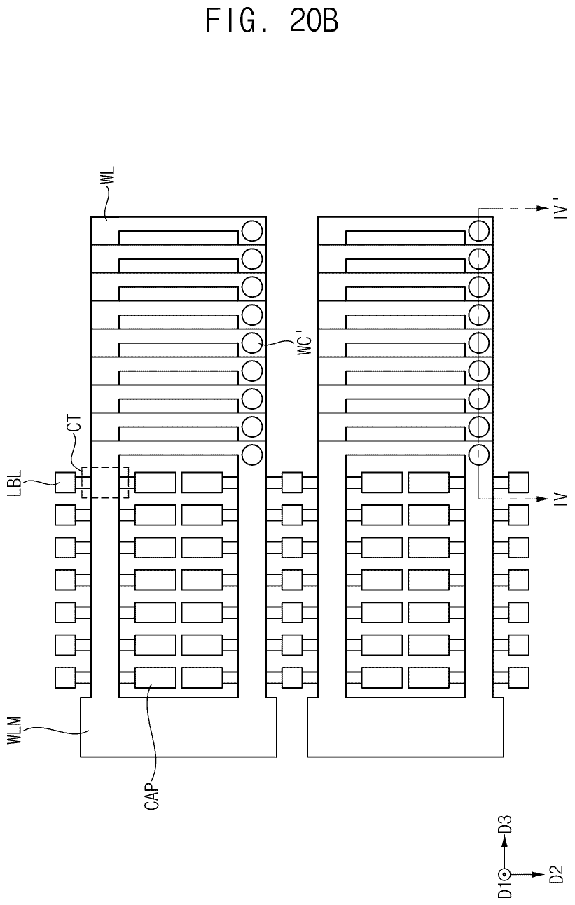

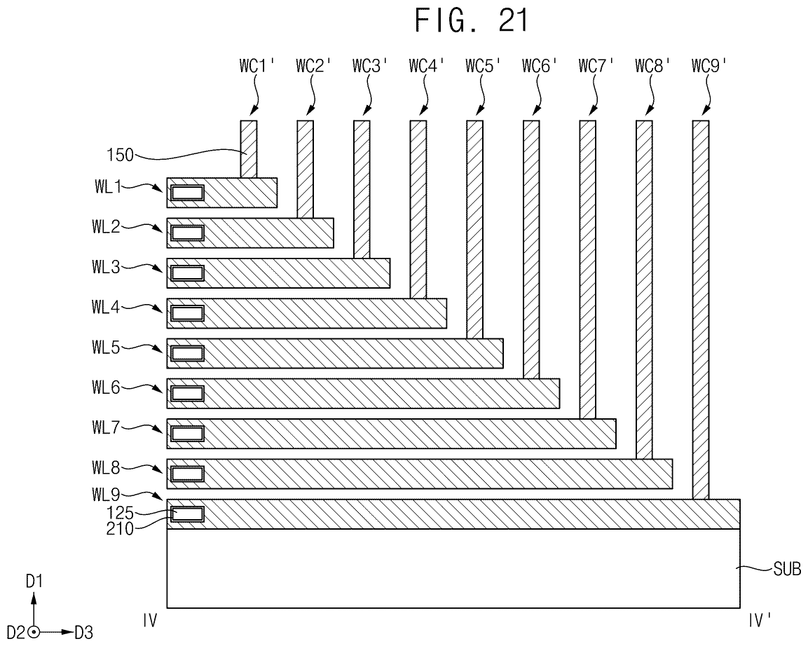

FIGS. 15, 16, 17, 18, 19, 20A, 20B and 21 are a perspective view, plan views and cross-sectional view for describing a semiconductor memory device according to example embodiments. FIG. 15 is a perspective view, FIGS. 16, 20A and 20B are plan views, FIG. 17 is a detailed cross-sectional view of a region X in FIG. 16, FIG. 18 is a detailed cross-sectional view of a region Y in FIG. 16, FIG. 19 is a cross-sectional view taken along a line III-III′ in FIG. 16, and FIG. 21 is a cross-sectional view taken along a line IV-IV′ in FIGS. 20A and 20B.

FIGS. 15, 16, 17, 18, 19, 20A, 20B and 21 illustrate a portion of the memory cell array of the semiconductor memory device and/or a portion of a sub-cell array included in the memory cell array.

Referring to FIGS. 15, 16, 17, 18 and 19, the semiconductor memory device may include wordlines WL, wordline contacts (or contact plugs) WC, merged wordlines WLM, local bitlines LBL and memory cells that are formed or disposed on a substrate SUB. The memory cells may include cell transistors CT and capacitors CAP. Although not illustrated in detail, the semiconductor memory device may further include an insulating interlayer that is disposed on the substrate SUB and covers the above structures.

The substrate SUB may include a semiconductor material, e.g., silicon, germanium, silicon-germanium, etc., or a III-V group compound semiconductor, such as GaP, GaAs, GaSb, etc. In some example embodiments, the substrate SUB may be a silicon-on-insulator (SOI) substrate or a germanium-on-insulator (GOI) substrate.

The substrate SUB may include a first region and a second region. The first region may be a cell region in which the memory cells are formed. The second region may be a region in which a merged wordline is formed by merging two wordlines connected to memory cells at the same level of the two adjacent cell string rows, and the wordline contacts WC for providing wordline voltages to wordlines connected to memory cells of the two adjacent cell string rows are formed.

The substrate SUB may further include a peripheral region in which peripheral circuit patterns including sense amplifiers, etc. are formed. The peripheral region may be a peripheral circuit region. In some example embodiments, the peripheral region may at least partially surround the first and second regions. In some example embodiments, the peripheral region may be disposed under or over the substrate SUB, so that the semiconductor memory device may have a cell over periphery (COP) structure or a periphery over cell (POC) structure, as described with reference to FIG. 5. The phrase “at least partially surround” may mean that the surrounding element may contact the surrounded element on at least one side or portion thereof, may contact the surrounded element on two sides, either opposite sides or proximate sides, may contact the surrounded element on more than two sides, or may even completely surround the surrounded element.

Each of the local bitlines LBL may extend in the first direction D1 on the first region of the substrate SUB, and a plurality of local bitlines LBL may be spaced apart from each other in the second and third directions D2 and D3. For example, structures 532 and 534 in FIG. 17 may represent or correspond to two local bitlines that extend in the first direction D1 and are spaced apart in the second direction D2. For example, the structures 532 and 534 may correspond to the local bitlines LBL1 and LBL2, respectively. For example, an upper surface of each of the local bitlines 532 and 534 may have a shape of, e.g., a polygon, a polygon with rounded corners, a circle, an ellipse, etc.

Between two adjacent local bitlines 532 and 534, two memory cells may be disposed at the same level. For example, each memory cell may include the capacitor CAP and the cell transistor CT. For example, in FIG. 17, a first cell transistor may be formed between a first capacitor 470 and the local bitline 532, and a second cell transistor may be formed between a second capacitor 471 and the local bitline 534. The first cell transistor may include a second source/drain layer 490 connected to the first capacitor 470, a channel 125 and a first source/drain layer 520 connected to the local bitline 532, and a gate structure 230 which surrounds the channel 125. The second cell transistor may include a fourth source/drain layer 491 connected to the second capacitor 471, a channel 126, a third source/drain layer 521 connected to the local bitline 534, and a gate structure 231 which surrounds the channel 126.

In some example embodiments, the first capacitor 470 may include a first capacitor electrode 380 having a pillar shape extending in the second direction D2, a dielectric pattern 440 surrounding the first capacitor electrode 380, and a second capacitor electrode 460 surrounding the dielectric pattern 440. For example, the dielectric pattern 440 may surround lower, upper and side surfaces of the first capacitor electrode 380, and the second capacitor electrode 460 may surround lower, upper and side surfaces of the dielectric pattern 440. However, example embodiments are not necessarily limited thereto, and for example, the first capacitor electrode 380 may have a shape of a hollow cylinder instead of the pillar shape, and the second capacitor electrode 460 may have a shape of a hollow cylinder instead of the pillar shape.

In some example embodiments, a cross-sectional view of the first capacitor electrode 380 in the third direction D3 may have a shape of a rectangle. However, example embodiments are not necessarily limited thereto, and the cross-sectional view of the first capacitor electrode 380 in the third direction D3 may have a different shape of, e.g., a polygon, a polygon with rounded corners, a circle, an ellipse, etc.

Each of the first and second capacitor electrodes 380 and 460 may include an electrically conductive material, e.g., a metal, a metal nitride, a metal silicide, doped silicon-germanium, etc. The dielectric pattern 440 may include a metal oxide having a high dielectric constant, e.g., hafnium oxide, zirconium oxide, etc., or a ferroelectric material. As used herein, the phrase, “high dielectric constant” may be understood to be a dielectric constant greater than that of silicon oxide.

The channel 125 may include a semiconductor material, e.g., silicon, germanium, silicon-germanium, etc. Alternatively, the channel 125 may include an oxide semiconductor material such as zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓO_{y}N_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), and/or indium gallium silicon oxide (InGaSiO).

Each of the first and second source/drain layers 520 and 490 may include substantially the same material as the channel 125, however, n-type or p-type impurities may be doped thereinto. The first and second source/drain layers 520 and 490 may include the same conductivity type of impurities.

In some example embodiments, the gate structure 230 may include a gate insulation pattern 210 covering lower, upper, and side surfaces of the channel 125, and a gate electrode 220 covering lower, upper, and side surfaces of the gate insulation pattern 210. Thus, the channel 125 may extend through the gate structure 230 in the second direction D2, and the gate structure 230 may have a gate all around (GAA) structure surrounding the channel 125.

Alternatively, the gate structure 230 may have a single gate structure or a double gate structure instead of the GAA structure. For example, the gate structure 230 may be disposed on or beneath the channel 125, or two gate structures 230 may be disposed on and beneath, respectively, the channel 125, instead of surrounding the channel 125.

As a result, the gate structure 230 electrically connected to the channel 125 may have various other types of structures.

In some example embodiments, the gate electrodes 220, which surround the channels 125 arranged along the third direction D3 at the same level and the gate insulation patterns 210 covering the channels 125 and are disposed adjacent to each other in the third direction D3, may be connected to each other, and thus may form one wordline WL extending in the third direction D3 on the first and second regions of the substrate SUB.

The gate electrode 220 may include an electrically conductive material, e.g., a metal, a metal nitride, a metal silicide, etc., and the gate insulation pattern 210 may include an oxide, e.g., silicon oxide, a metal oxide, etc.

Two adjacent wordlines WL may be formed integrally to form one merged wordline WLM on the second region of the substrate SUB. The merged wordline WLM may be connected to memory cells disposed at the same level of two adjacent cell string rows (e.g., two adjacent cell rows) which do not share a local bitline.

Each of the wordline contacts WC may extend in the first direction D1 on the second region of the substrate SUB, and may be electrically connected to one of the wordlines WL. For example, as illustrated in FIG. 19, nine wordline contacts WC1, WC2, WC3, WC4, WC5, WC6, WC7, WC8 and WC9 may be electrically connected to nine wordlines WL1, WL2, WL3, WL4, WL5, WL6, WL7, WL8 and WL9, respectively. In some example embodiments, the number and arrangement of the wordline contacts WC1, WC2, WC3, WC4, WC5, WC6, WC7, WC8 and WC9 may be implemented in various manners.

In some example embodiments, some wordline contacts may be formed to penetrate at least one wordline and/or at least one merged wordline. For example, the wordline contact WC1 may be electrically connected to the wordline WL1 without penetrating the other wordlines. For example, the wordline contact WC2 may be electrically connected to the wordline WL2 by penetrating the wordline WL1. The wordline contact WC3 may be electrically connected to the wordline WL3 by penetrating the wordlines WL1 and WL2.

In some example embodiments, each of the wordline contacts WC1, WC2, WC3, WC4, WC5, WC6, WC7, WC8 and WC9 may include a conductive material 150 and an insulating material 140 surrounding the conductive material 150. For example, the conductive material 150 may include an electrically conductive material, e.g., a metal, a metal nitride, a metal silicide, etc. For example, when the wordline contact WC2 includes the insulating material 140, the wordline contact WC2 may be electrically connected to the wordline WL2 and may be electrically insulated from the wordline WL1.

Referring to FIGS. 20A, 20B and 21, an arrangement and structure of wordline contacts WC′ may be changed, as compared with the example of FIGS. 15, 16, 17, 18 and 19. The descriptions repeated with or overlapping with descriptions of FIGS. 15, 16, 17, 18 and 19 will be omitted for brevity.

The substrate SUB may further include a third region. For example, the third region may be formed adjacent to one side of the first region in the third direction D3. However, example embodiments are not limited thereto, and the third region may be formed adjacent to both sides of the first region in the third direction D3, or may at least partially surround the first region.

Each of the wordline contacts WC′ may extend in the first direction D1 on the third region of the substrate SUB, and may be electrically connected to each of the wordlines WL. For example, in a cross-sectional view, the wordlines WL may be disposed in a scalariform pattern, or in a stepped shape (e.g., in the third direction D3 in a stepwise manner) on the third region of the substrate SUB. For example, the wordlines WL may extend in a stepwise manner in the third direction D3 from the uppermost level to the lowermost level. For example, as illustrated in FIG. 21, nine wordline contacts WC1′, WC2′, WC3′, WC4′, WC5′, WC6′, WC7′, WC8′ and WC9′ may be electrically connected to nine wordlines WL1, WL2, WL3, WL4, WL5, WL6, WL7, WL8 and WL9, respectively. In some example embodiments, on the third region of the substrate SUB, the wordlines WL that are disposed in a stepped shape may be separated from each other as illustrated in FIG. 20A, or two adjacent wordlines among the wordlines WL that are disposed in a stepped shape may be connected to each other as illustrated in FIG. 20B.

In some example embodiments, each of the wordline contacts WC1′, WC2′, WC3′, WC4′, WC5′, WC6′, WC7′, WC8′ and WC9′ may include a conductive material 150. Unlike the example of FIG. 19, the wordline contacts WC1′, WC2′, WC3′, WC4′, WC5′, WC6′, WC7′, WC8′ and WC9′ may not penetrate the wordlines WL, and thus the insulating material 140 surrounding the wordline contact 150 may be omitted.

In some example embodiments, the semiconductor memory device according to example embodiments may be implemented by combining two or more of the examples described with reference to FIGS. 1 through 21.

FIG. 22 is a block diagram illustrating a semiconductor memory device according to example embodiments.

Referring to FIG. 22, a semiconductor memory device 1200 may include a peripheral circuit 1201 and a memory cell array 1300. The peripheral circuit 1201 may include a control logic circuit 1210, an address register 1220, a bank control logic circuit 1230, a row address multiplexer 1240, a refresh counter 1245, a column address latch 1250, a row decoder 1260, a column decoder 1270, a sense amplifier unit 1285, an input/output (I/O) gating circuit 1290 and a data I/O buffer 1295. For example, the semiconductor memory device 1200 may be one of various volatile memory devices such as a dynamic random access memory (DRAM) device.

The memory cell array 1300 may include first to eighth bank arrays 1310 to 1380 (e.g., first to eighth bank arrays 1310, 1320, 1330, 1340, 1350, 1360, 1370 and 1380). The row decoder 1260 may include first to eighth bank row decoders 1260a to 1260h connected respectively to the first to eighth bank arrays 1310 to 1380. The column decoder 1270 may include first to eighth bank column decoders 1270a to 1270h connected respectively to the first to eighth bank arrays 1310 to 1380. The sense amplifier unit 1285 may include first to eighth bank sense amplifiers 1285a to 1285h connected respectively to the first to eighth bank arrays 1310 to 1380.

The first to eighth bank arrays 1310 to 1380, the first to eighth bank row decoders 1260a to 1260h, the first to eighth bank column decoders 1270a to 1270h, and the first to eighth bank sense amplifiers 1285a to 1285h may form first to eighth banks. Each of the first to eighth bank arrays 1310 to 1380 may include a plurality of wordlines WL, a plurality of bitlines BL, and a plurality of memory cells MC that are at intersections of the wordlines WL and the bitlines BL. For example, each of the plurality of bitlines BL may include the local bitline LBL and the global bitline GBL that are selectively connected by the local bitline multiplexer.

Although FIG. 22 illustrates the semiconductor memory device 1200 including eight banks (and eight bank arrays, eight row decoders, and so on), the semiconductor memory device 1200 may include any number of banks; for example, one, two, four, eight, sixteen, or thirty two banks, or any number therebetween one and thirty two.

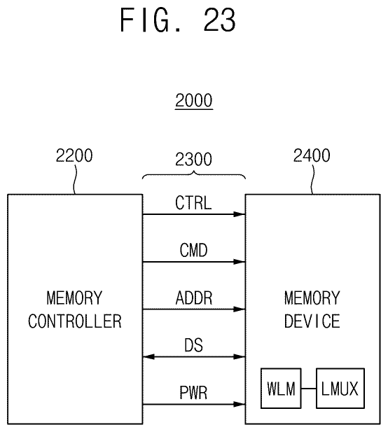

The address register 1220 may receive the address ADDR including a bank address BANK_ADDR, a row address ROW_ADDR, and a column address COL_ADDR from a memory controller (e.g., a memory controller 2200 in FIG. 23). The address register 1220 may provide the received bank address BANK_ADDR to the bank control logic circuit 1230, may provide the received row address ROW_ADDR to the row address multiplexer 1240, and may provide the received column address COL_ADDR to the column address latch 1250.

The bank control logic circuit 1230 may generate bank control signals in response to the bank address BANK_ADDR. One of the first to eighth bank row decoders 1260a to 1260h corresponding to the bank address BANK_ADDR may be activated in response to the bank control signals, and one of the first to eighth bank column decoders 1270a to 1270h corresponding to the bank address BANK_ADDR may be activated in response to the bank control signals.

The row address multiplexer 1240 may receive the row address ROW_ADDR from the address register 1220, and may receive a refresh row address REF_ADDR from the refresh counter 1245. The row address multiplexer 1240 may selectively output the row address ROW_ADDR or the refresh row address REF_ADDR as a row address RA. The row address RA that is output from the row address multiplexer 1240 may be applied to the first to eighth bank row decoders 260a to 260h.

The activated one of the first to eighth bank row decoders 1260a to 1260h may decode the row address RA that is output from the row address multiplexer 1240, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 1250 may receive the column address COL_ADDR from the address register 1220, and may temporarily store the received column address COL_ADDR. In some example embodiments, in a burst mode, the column address latch 1250 may generate column addresses that increment from the received column address COL_ADDR. The column address latch 1250 may apply the temporarily stored or generated column address to the first to eighth bank column decoders 1270a to 1270h.

The activated one of the first to eighth bank column decoders 1270a to 1270h may decode the column address COL_ADDR that is output from the column address latch 1250, and may control the I/O gating circuit 1290 to output data corresponding to the column address COL_ADDR.

The I/O gating circuit 1290 may include circuitry configured to gate input/output data. The I/O gating circuit 1290 may further include read data latches configured to store data that is output from the first to eighth bank arrays 1310 to 1380, and may also include write control devices for writing data to the first to eighth bank arrays 1310 to 1380.

Data DAT read from one of the first to eighth bank arrays 1310 to 1380 may be sensed by a sense amplifier connected to the one bank array from which the data DAT is to be read, and may be stored in the read data latches. The data DAT stored in the read data latches may be provided to the memory controller via the data I/O buffer 1295. Data DAT to be written in one of the first to eighth bank arrays 1310 to 1380 may be provided to the I/O gating circuit 1290 via the data I/O buffer 1295 from the memory controller, and the I/O gating circuit 1290 may write the data DAT in the one bank array through the write drivers.

The control logic circuit 1210 may control operations of the semiconductor memory device 1200. For example, the control logic circuit 1210 may generate control signals for the semiconductor memory device 1200 to perform the write operation and/or the read operation. The control logic circuit 1210 may include a command decoder 1211 that decodes a command CMD received from the memory controller, and a mode register 1212 that sets an operation mode of the semiconductor memory device 1200. In some example embodiments, operations described herein as being performed by the control logic circuit 1210 may be performed by processing circuitry. For example, the command decoder 1211 may generate the control signals corresponding to the command CMD by decoding a write enable signal, a row address strobe signal, a column address strobe signal, a chip selection signal, etc.

The semiconductor memory device 1200 may be the semiconductor memory device according to example embodiments described above with reference to FIGS. 1 through 21. For example, the semiconductor memory device 1200 may be implemented with the wordline merging structure in which two adjacent wordlines connected to two memory cells, which are disposed at the same level and do not share a local bitline, are merged into one wordline. In addition, the local bitline multiplexer that controls the electrical connection between the local bitline and the global bitline may be disposed on each local bitline, and sensing operation is performed on the memory cell connected to the local bitline which is connected to the global bitline through the local bitline multiplexer. The sense amplifier performing the sensing operation may be connected to the global bitline. Accordingly, the number of sense amplifiers may be reduced and the layout size restriction of each sense amplifier may be released because the sense amplifier is not connected to each local bitline and the layout size of the sense amplifier is not limited by the width of the memory cell in the third direction D3, thereby improving electrical characteristics and reliability of the semiconductor memory device 1200. For example, the sense amplifiers may be included in the sense amplifier unit 1285.

FIG. 23 is a block diagram illustrating a memory system according to example embodiments.

Referring to FIG. 23, a memory system 2000 includes a memory controller 2200 and a semiconductor memory device 2400. The memory system 2000 may further include a plurality of signal lines 2300 that electrically connect the memory controller 2200 with the semiconductor memory device 2400.

The semiconductor memory device 2400 is controlled by the memory controller 2200. For example, based on requests from a host (not illustrated), the memory controller 2200 may store (e.g., write or program) data into the semiconductor memory device 2400, or may retrieve (e.g., read or sense) data from the semiconductor memory device 2400. The semiconductor memory device 2400 may be the memory device according to example embodiments. For example, the semiconductor memory device 2400 may include a merged wordline WLM implemented by merging wordlines connected to memory cells at the same level of two adjacent cell string rows (e.g., two adjacent cell rows), and a hierarchical bitline structure in which a local bitline multiplexer LMUX controls electrical connection between the corresponding local bitline and the corresponding global bitline.

The plurality of signal lines 2300 may include control lines, command lines, address lines, data input/output (I/O) lines and power lines. The memory controller 2200 may transmit a command CMD, an address ADDR and a control signal CTRL to the semiconductor memory device 2400 via the command lines, the address lines and the control lines, may exchange a data signal DS with the semiconductor memory device 2400 via the data I/O lines, and may supply a power supply voltage PWR to the semiconductor memory device 2400 via the power lines. Although not illustrated in detail, the plurality of signal lines 2300 may further include data strobe signal (DQS) lines for transmitting a DQS signal.

The example embodiments may be applied to various electronic devices and systems that include the semiconductor memory devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor memory device comprising:
a plurality of cell string rows arranged on a first substrate, each cell string row being spaced apart from an adjacent cell string row in a second direction and including a plurality of cell strings arranged along a third direction, and each cell string including memory cells stacked vertically along a first direction, wherein the first direction is perpendicular to an upper surface of the first substrate, the second and third directions are parallel to the upper surface of the first substrate and intersect each other;
a plurality of local bitlines on the first substrate, each of the plurality of local bitlines being electrically connected to memory cells of corresponding cell string, each of the plurality of local bitlines extending in the first direction;
a plurality of wordlines on the first substrate, each of the plurality of wordlines being electrically connected to the memory cells disposed at the same level of the corresponding cell string row, each of the plurality of wordlines extending in the third direction;
a plurality of global bitlines selectively and electrically connected to the plurality of local bitlines;
a plurality of local bitline multiplexers configured to control electrical connections between the plurality of local bitlines and the plurality of global bitlines; and
a plurality of sense amplifiers electrically connected to the plurality of global bitlines, and configured to perform sensing operations on memory cells connected to the local and global bitlines,
wherein memory cells disposed at the same level of two adjacent cell string rows, which are connected to different local bitlines, are electrically connected to a merged wordline.

2. The semiconductor memory device of claim 1, wherein each of the plurality of local bitline multiplexers includes:
a first transistor connected between a first local bitline among the plurality of local bitlines and a first global bitline among the plurality of global bitlines; and
a second transistor connected to the first local bitline and a precharge voltage.

3. The semiconductor memory device of claim 1, wherein, each of the plurality of local bitline multiplexers includes:
a first transistor connected between a first local bitline among the plurality of local bitlines and a first global bitline among the plurality of global bitlines; and
a second transistor connected between the first local bitline and a second global bitline among the plurality of global bitlines.

4. The semiconductor memory device of claim 1, wherein, each sense amplifier is configured to detect and amplify voltage variation at a global bitline which results from charge sharing between a memory cell capacitor and the local and global bitlines electrically connected to the memory cell.

5. The semiconductor memory device of claim 1, wherein the plurality of local bitline multiplexers and the plurality of global bitlines are disposed on the first substrate, and the plurality of sense amplifiers are disposed on a second substrate different from the first substrate.

6. The semiconductor memory device of claim 5, wherein the first and second substrates are bonded to each other after the plurality of local bitline multiplexers, the plurality of global bitlines and the plurality of sense amplifiers are formed on the first and second substrates respectively.

7. The semiconductor memory device of claim 1, wherein the plurality of local bitline multiplexers, the plurality of global bitlines and the plurality of sense amplifiers are disposed on a second substrate different from the first substrate.

8. The semiconductor memory device of claim 1, wherein the plurality of global bitlines are formed with conductive patterns of the same conductive layer, and each of the plurality of global bitlines extends in the second direction.

9. The semiconductor memory device of claim 1, wherein the plurality of global bitlines are formed with conductive patterns of two conductive layers that are disposed at different levels in the first direction, and two adjacent global bitlines among the plurality of global bitlines are electrically insulated from each other and intersect in a plan view.

10. The semiconductor memory device of claim 1, further comprising:
a plurality of wordline contacts on the first substrate, each of the plurality of wordline contacts electrically connected to a corresponding wordline among the plurality of wordlines and extending in the first direction.

11. The semiconductor memory device of claim 10, wherein at least one of the plurality of wordline contacts penetrates at least one of the plurality of wordlines.

12. The semiconductor memory device of claim 10, wherein, the plurality of wordlines extend to a first region of the first substrate, forming a stepped shape in a cross-sectional view, and each of the plurality of wordline contacts are electrically connected to a corresponding wordline among the plurality of wordlines on the first region.

13. The semiconductor memory device of claim 1, further comprising:
a plurality of sub-wordline drivers electrically connected to the plurality of wordlines, the plurality of sub-wordline drivers configured to drive the plurality of wordlines.

14. A semiconductor memory device comprising:
a first local bitline and a second local bitline on a first substrate, each of the first and second local bitlines extending in a first direction perpendicular to an upper surface of the first substrate, the first and second local bitlines being spaced apart from each other in a second direction parallel to the upper surface of the first substrate;
first memory cells on the first substrate, the first memory cells stacked vertically along the first direction between the first and second local bitlines and being electrically connected to the first local bitline;
second memory cells on the first substrate, the second memory cells stacked vertically along the first direction between the first and second local bitlines and being electrically connected to the second local bitline;
wordlines on the first substrate, each of the wordlines extending in a third direction parallel to the upper surface of the first substrate and intersecting the second direction, each of the wordlines being electrically connected to memory cells disposed at the same level among the first and second memory cells;
a first global bitline and a second global bitline selectively and electrically connected to the first local bitline and the second local bitline;
a first local bitline multiplexer and a second local bitline multiplexer configured to control electrical connections between the first and second local bitlines and the first and second global bitlines; and
a first sense amplifier and a second sense amplifier electrically connected to the first global bitline and the second global bitline respectively, the first and second sense amplifiers configured to perform sensing operations on memory cells electrically connected to the first and second local bitlines and the first and second global bitlines.

15. The semiconductor memory device of claim 14, wherein the first local bitline multiplexer includes:
a first transistor connected between the first local bitline and the first global bitline; and
a second transistor connected between the first local bitline and a precharge voltage.

16. The semiconductor memory device of claim 14, wherein the first local bitline multiplexer includes:
a first transistor connected between the first local bitline and the first global bitline; and
a second transistor connected between the first local bitline and the second global bitline.

17. The semiconductor memory device of claim 14, further comprising:
a third local bitline and a fourth local bitline on the first substrate, each of the third and fourth local bitlines extending in the first direction, the third and fourth local bitlines being spaced apart from each other in the second direction; and
a third local bitline multiplexer and a fourth local bitline multiplexer configured to control electrical connections between the third and fourth local bitlines and the first and second global bitlines.

18. The semiconductor memory device of claim 17, wherein the first and second global bitlines are formed with conductive patterns of a first conductive layer, and each of the first and second global bitlines extends in the second direction, each of the first and third local bitline multiplexers is configured to control an electrical connection between a respective one of the first and third local bitlines and the first global bitline, and each of the second and fourth local bitline multiplexers is configured to control an electrical connection between a respective one of the second and fourth local bitlines and the second global bitline.

19. The semiconductor memory device of claim 17, wherein the first and second global bitlines are formed with conductive patterns of a first conductive layer and a second conductive layer that are disposed at different levels in the first direction, the first and second global bitlines are electrically insulated from each other and intersect each other in a plan view, each of the first and fourth local bitline multiplexers is configured to control an electrical connection between a respective one of the first and fourth local bitlines and the first global bitline, and each of the second and third local bitline multiplexers is configured to control an electrical connection between a respective one of the second and third local bitlines and the second global bitline.

20. A memory system comprising:
a memory controller; and
a semiconductor memory device controlled by the memory controller, the semiconductor memory device including:
a plurality of memory cells on a first substrate, the plurality of memory cells being arranged along a first direction, a second direction and a third direction, the first direction being perpendicular to an upper surface of the first substrate, the second and third directions being parallel to the upper surface of the first substrate and intersecting each other;
a plurality of local bitlines on the first substrate, the plurality of local bitlines being electrically connected to the plurality of memory cells, each of the plurality of local bitlines extending in the first direction,
a plurality of wordlines on the first substrate, the plurality of wordlines being electrically connected to the plurality of memory cells, each of the plurality of wordlines extending in the third direction;
a plurality of global bitlines selectively and electrically connected to the plurality of local bitlines;
a plurality of local bitline multiplexers configured to control electrical connections between the plurality of local bitlines and the plurality of global bitlines; and
a plurality of sense amplifiers electrically connected to the plurality of global bitlines, the plurality of sense amplifiers configured to perform sensing operations on memory cells connected to the plurality of local bitlines and the plurality of global bitlines, and
wherein memory cells, which are disposed at the same level, adjacent in the second direction, and connected to different local bitlines, are electrically connected to a merged wordline.
